(19) United States
(12) Patent Application Publication
(10) Pub. No.: US 2025/0294750 A1
(43) Pub. Date: Sep. 18, 2025

(54) SEMICONDUCTOR MEMORY DEVICE AND METHOD FOR MANUFACTURING SEMICONDUCTOR MEMORY DEVICE

(71) Applicant: Kioxia Corporation, Tokyo (JP)

(72) Inventor: Akitsugu HATAZAKI, Yokkaichi (JP)

(73) Assignee: Kioxia Corporation, Tokyo (JP)

(21) Appl. No.: 18/973,606

(22) Filed: Dec. 9, 2024

(30) Foreign Application Priority Data
Mar. 18, 2024 (JP) 2024-042168

(51) Int. Cl. H10B 43/27; H01L 23/00; H01L 25/065; H01L 25/18; H10B 80/00

(52) U.S. Cl. CPC H10B 43/27; H01L 24/08; H01L 25/0657; H01L 25/18; H10B 80/00; H01L 2224/08145; H01L 2924/1431; H01L 2924/14511

(57) ABSTRACT

A semiconductor memory device of an embodiment includes a stopper layer that is disposed above a part of a staircase portion; and a plurality of first contacts that extends from a height position above a stacked body at positions overlapping the staircase portion in a stacking direction of the stacked body, and is connected to portions where a plurality of first conductive layers on a lower layer side including a lowermost conductive layer among the plurality of conductive layer is processed in a staircase shape, in which the plurality of first contacts penetrates the stopper layer and extends in the stacking direction, and the plurality of second contacts extends in the stacking direction without penetrating the stopper layer.

### CROSS-REFERENCE TO RELATED APPLICATIONS

This application is based upon and claims the benefit of priority from Japanese Patent Application No. 2024-042168, filed on Mar. 18, 2024; the entire contents of which are incorporated herein by reference.

### FIELD

Embodiments described herein relate generally to a semiconductor memory device and a method for manufacturing the semiconductor memory device.

### BACKGROUND

In a semiconductor memory device such as a three-dimensional nonvolatile memory, memory cells are three-dimensionally disposed in a stacked body in which a plurality of conductive layers is stacked one by one while being separated from each other. These conductive layers are processed into a staircase shape in a partial region of the stacked body, and a contact is connected to each of the conductive layers. A problem is how to form contacts that are respectively connected to the plurality of conductive layers belonging to different layers of the stacked body and having a height difference.

### BRIEF DESCRIPTION OF THE DRAWINGS

FIGS. 1A and 1B are views illustrating a schematic configuration example of a semiconductor memory device according to an embodiment;

FIGS. 2A to 2D are cross-sectional views illustrating an example of a configuration of the semiconductor memory device according to the embodiment;

FIGS. 3A to 3E are cross-sectional views sequentially illustrating a part of a procedure of a method for manufacturing the semiconductor memory device according to the embodiment;

FIGS. 4A to 4C are cross-sectional views sequentially illustrating a part of a procedure of the method for manufacturing the semiconductor memory device according to the embodiment;

FIGS. 5A to 5C are cross-sectional views sequentially illustrating a part of a procedure of the method for manufacturing the semiconductor memory device according to the embodiment;

FIGS. 6A to 6C are cross-sectional views sequentially illustrating a part of a procedure of the method for manufacturing the semiconductor memory device according to the embodiment;

FIGS. 7A to 7C are cross-sectional views sequentially illustrating a part of a procedure of the method for manufacturing the semiconductor memory device according to the embodiment;

FIGS. 8A to 8D are cross-sectional views sequentially illustrating a part of a procedure of the method for manufacturing the semiconductor memory device according to the embodiment;

FIGS. 9A to 9C are cross-sectional views sequentially illustrating a part of a procedure of the method for manufacturing the semiconductor memory device according to the embodiment;

FIGS. 10A to 10C are cross-sectional views sequentially illustrating a part of a procedure of the method for manufacturing the semiconductor memory device according to the embodiment;

FIGS. 11A to 11C are cross-sectional views sequentially illustrating a part of a procedure of the method for manufacturing the semiconductor memory device according to the embodiment;

FIG. 12 is a cross-sectional view along an X direction illustrating an example of a configuration of a staircase region included in a semiconductor memory device according to a modification of the embodiment;

FIGS. 13A to 13D are views sequentially illustrating a part of a procedure of a method for manufacturing the semiconductor memory device according to the modification of the embodiment;

FIGS. 14A and 14B are views sequentially illustrating a part of a procedure of the method for manufacturing the semiconductor memory device according to the modification of the embodiment;

FIGS. 15A and 15B are views sequentially illustrating a part of a procedure of the method for manufacturing the semiconductor memory device according to the modification of the embodiment;

FIGS. 16A and 16B are views sequentially illustrating a part of a procedure of the method for manufacturing the semiconductor memory device according to the modification of the embodiment;

FIGS. 17A and 17B are views sequentially illustrating a part of a procedure of the method for manufacturing the semiconductor memory device according to the modification of the embodiment; and

FIGS. 18A and 18B are views sequentially illustrating a part of a procedure of the method for manufacturing the semiconductor memory device according to the modification of the embodiment.

### DETAILED DESCRIPTION

A semiconductor memory device of an embodiment includes: a stacked body in which a plurality of conductive layers is stacked apart from each other; a staircase portion that is disposed in a part of the stacked body and in which the plurality of conductive layers is processed in a staircase shape; a stopper layer that is disposed above a part of the staircase portion; a plurality of first contacts that extends from a height position above the stacked body at positions overlapping the staircase portion in a stacking direction of the stacked body, and is connected to portions where a plurality of first conductive layers on a lower layer side including a lowermost conductive layer among the plurality of conductive layer is processed in the staircase shape; and a plurality of second contacts that extends from the height position above the stacked body at positions overlapping the staircase portion in the stacking direction and is connected to portions where a plurality of second conductive layers on an upper layer side including an uppermost conductive layer among the plurality of conductive layers is processed in the staircase shape, wherein the stopper layer is at least disposed at a position overlapping the portions where the plurality of first conductive layers is processed in the staircase shape in the stacking direction, the plurality of first contacts penetrates the stopper layer and extends in the stacking direction, and the plurality of second contacts extends in the stacking direction without penetrating the stopper layer.

Hereinafter, embodiments of the present invention will be described in detail with reference to the drawings. Note that the present invention is not limited by the embodiments described below. In addition, constituent elements in the embodiments described below include those that can be easily assumed by those skilled in the art or those that are substantially the same.

### (Configuration Example of Semiconductor Memory Device)

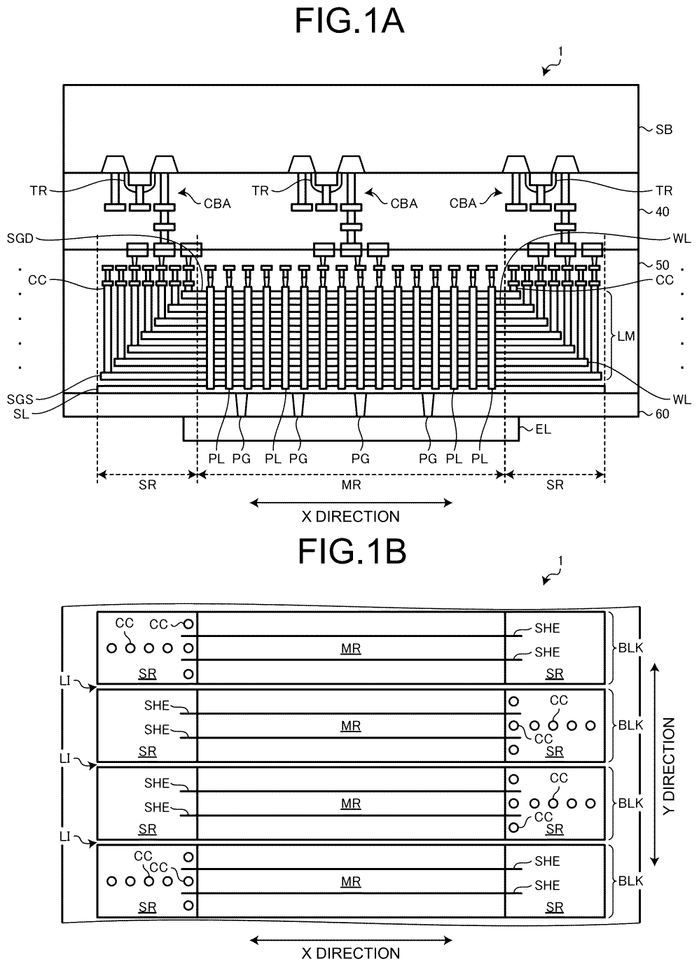

FIGS. 1A and 1B are views illustrating a schematic configuration example of a semiconductor memory device 1 according to an embodiment. More specifically, FIG. 1A is a cross-sectional view of the semiconductor memory device 1 along an X direction, and FIG. 1B is a schematic plan view illustrating a layout of the semiconductor memory device 1.

However, in FIG. 1A, hatching is omitted in consideration of visibility of the drawing. In addition, in FIG. 1A, configurations that do not necessarily exist in the same cross section are illustrated, and a part of upper layer wiring and the like is omitted.

In addition, in the present specification, both the X direction and the Y direction are directions along the orientation of surfaces of word lines WL, and the X direction and the Y direction are orthogonal to each other. In addition, the electrical lead-out direction of the word lines WL may be referred to as a first direction, and the first direction is a direction along the X direction. In addition, a direction intersecting the first direction may be referred to as a second direction, and the second direction is a direction along the Y direction. However, since the semiconductor memory device 1 may include a manufacturing error, the first direction and the second direction are not necessarily orthogonal to each other.

As illustrated in FIG. 1A, the semiconductor memory device 1 includes an electrode film EL, a source line SL, one or more select gate lines SGS, a plurality of word lines WL, one or more select gate lines SGD, and a semiconductor substrate SB on which peripheral circuits CBA are provided in order from the lower side of the drawing.

The source line SL is disposed on the electrode film EL via an insulating layer 60. A plurality of plugs PG is disposed in the insulating layer 60, and the source line SL and the electrode film EL maintain electrical conduction via the plugs PG. Although not illustrated, an electrode pad for supplying power and a signal from the outside to the semiconductor memory device 1 is provided in the same layer as the electrode film EL. The select gate lines SGS, the plurality of word lines WL, and the select gate lines SGD are stacked in this order on the source line SL to constitute a stacked body LM.

As illustrated in FIGS. 1A and 1B, a memory region MR is disposed at a central portion of the plurality of word lines WL in the X direction, and staircase regions SR are disposed at both end portions of the plurality of word lines WL in the X direction. The memory region MR and the staircase regions SR are divided into a plurality of regions by a plurality of plate-like contacts LI penetrating the plurality of word lines WL and extending in the direction along the X direction.

Note that regions disposed between the plate-like contacts LI adjacent in the Y direction and including the memory region MR and the staircase regions SR are referred to as block regions BLK. As will be described below, the memory region MR includes a plurality of memory cells that holds data in a nonvolatile manner, and the above-described block region BLK is an erase unit of the data.

In addition, between the plate-like contacts LI adjacent in the Y direction, a plurality of separation layers SHE penetrating the select gate lines SGD and extending in the direction along the X direction is disposed. The plurality of separation layers SHE extends in the direction along the X direction over the entire memory region MR and reaches a part of the staircase regions SR at both end portions in the X direction.

In the memory region MR, a plurality of pillars PL penetrating the word lines WL and the select gate lines SGD and SGS in the stacking direction is disposed. The lower ends of the pillars PL reach the source line SL. A plurality of memory cells is formed at intersection portions of the pillars PL and the word lines WL. As a result, the semiconductor memory device 1 is configured as, for example, a three-dimensional nonvolatile memory in which memory cells are three-dimensionally disposed in the memory region MR.

In the staircase regions SR, the plurality of word lines WL and the select gate lines SGD and SGS are processed in a staircase shape and terminate. At this time, as the distance from the memory region MR increases in the X direction, the plurality of word lines WL and the select gate lines SGD and SGS constituting terrace portions shift from the upper layer side to the lower layer side, so that the height position of the terrace portion lowers toward the source line SL side.

Note that the separation layers SHE described above extend from the memory region MR to a portion of the staircase regions SR where the select gate lines SGD are processed into a staircase shape. As a result, in one block region BLK, the select gate lines SGD are separated into a plurality of regions. In other words, the separation layers SHE penetrate the portions above the plurality of word lines WL, so that these upper layer portions are partitioned into patterns of the plurality of select gate lines SGD.

Contacts CC connected to the word lines WL and the select gate lines SGD and SGS of layers are disposed at terrace portions of steps including the plurality of word lines WL and the select gate lines SGD and SGS. In the word lines WL and the select gate lines SGS, one contact CC is connected for each layer. In the select gate lines SGD, one contact CC is connected for each section separated by the separation layers SHE per layer.

Here, in one block region BLK, the plurality of contacts CC is disposed on one of the staircase regions SR on both sides in the X direction. In addition, when viewed on one side in the X direction, for example, the plurality of contacts CC is disposed every two block regions BLK.

That is, in the example of FIG. 1B, in the uppermost block region BLK in the drawing, a plurality of contacts CC is disposed, for example, in the staircase region SR on the left side in the drawing out of the staircase regions SR at both end portions in the X direction. In addition, in the block regions BLK one below and two below the above-described block region BLK, a plurality of contacts CC is disposed in the staircase region SR on the right side in the drawing out of the staircase regions SR at both end portions in the X direction. Further, in the lowermost block region BLK in the drawing, a plurality of contacts CC is disposed in the staircase region SR again on the left side in the drawing.

Accordingly, the contacts CC of the staircase regions SR at both end portions in the X direction illustrated in FIG. 1A belong to different block regions BLK, and are not actually located in the same cross section.

The word lines WL and the like stacked in multiple layers are individually lead out by these contacts CC. More specifically, a write voltage, a read voltage, and the like are applied from these contacts CC to the memory cells included in the memory region MR at the central portion of the plurality of word lines WL via the word lines WL at the same height positions as the memory cells.

The plurality of word lines WL, the select gate lines SGD and SGS, the pillars PL, and the contacts CC are covered with an insulating layer 50. The insulating layer 50 also extends around these configurations.

The semiconductor substrate SB above the insulating layer 50 is, for example, a silicon substrate or the like. The peripheral circuits CBA including transistors TR, wiring, and the like are disposed on the surface of the semiconductor substrate SB. Various voltages applied from the contacts CC to the memory cells are controlled by the peripheral circuits CBA electrically connected to the contacts CC. As a result, the peripheral circuits CBA control the electrical operation of the memory cells.

The peripheral circuits CBA are covered with an insulating layer 40, and the insulating layer 40 and the insulating layer 50 covering the plurality of word lines WL and the like are joined to form the semiconductor memory device 1 including the configurations of the plurality of word lines WL and the select gate lines SGD and SGS, the pillars PL, the contacts CC, and the like, and the peripheral circuits CBA.

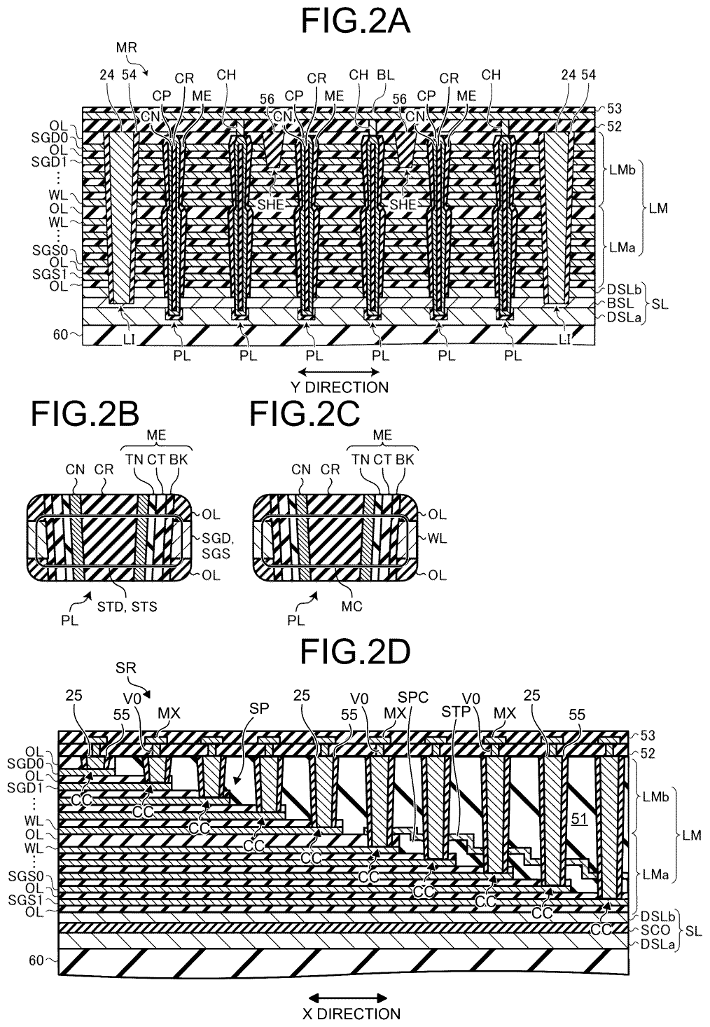

Next, a detailed configuration example of the semiconductor memory device 1 will be described with reference to FIGS. 2A to 2D. FIG. 2 is a cross-sectional view illustrating an example of a configuration of the semiconductor memory device 1 according to the embodiment.

More specifically, FIG. 2A is a cross-sectional view along the Y direction of the memory region MR of the semiconductor memory device 1. In FIG. 2A, structures below the insulating layer 60 and above an insulating layer 53 described below are omitted.

FIG. 2B is an enlarged cross-sectional view of the pillar PL at the height position of the select gate line SGD or SGS. FIG. 2C is an enlarged cross-sectional view of the pillar PL at the height position of the word line WL.

FIG. 2D is a cross-sectional view along the X direction in the staircase region SR of the semiconductor memory device 1. In FIG. 2D, structures below the insulating layer 60 and above the insulating layer 53 described below are omitted.

Note that, in the present specification, the direction in which the terrace surface of the word line WL of each step in the staircase region SR faces is defined as the upward direction in the semiconductor memory device 1.

As illustrated in FIG. 2A, the source line SL has a multilayer structure in which, for example, a lower source line DSLa, an intermediate source line BSL, and an upper source line DSLb are stacked in this order on the insulating layer 60. Note that the intermediate source line BSL is disposed below the memory region MR of the stacked body LM.

The lower source line DSLa, the intermediate source line BSL, and the upper source line DSLb are, for example, polysilicon layers. Among them, at least the intermediate source line BSL may be a conductive polysilicon layer or the like in which impurities are diffused.

Note that the source line SL is connected to the peripheral circuits CBA via the electrode film EL by penetrating contacts, which are not illustrated, extending from the electrode film EL to the peripheral circuits CBA in the insulating layer 50 described above outside the stacked body LM.

The stacked body LM is disposed on the source line SL. The stacked body LM includes stacked bodies LMa and LMb in which a plurality of word lines WL and a plurality of insulating layers OL are alternately stacked one by one.

The stacked body LMa is disposed above the source line SL. A plurality of select gate lines SGS0 and SGS1 is disposed in this order from the upper layer side of the stacked body LMa via the insulating layers OL further below the lowermost word line WL of the stacked body LMa. The stacked body LMb is disposed on the stacked body LMa. A plurality of select gate lines SGD0 and SGD1 is disposed in this order from the upper layer side of the stacked body LMb via the insulating layers OL further above the uppermost word line WL of the stacked body LMb.

However, the number of word lines WL and select gate lines SGD and SGS stacked in the stacked body LM is arbitrary. The word lines WL and the select gate lines SGD and SGS are, for example, a tungsten layer or a molybdenum layer. The insulating layers OL are, for example, a silicon oxide layer of the like.

The upper surface of the stacked body LM is covered with an insulating layer 52. The insulating layer 52 is covered with the insulating layer 53. Each of the insulating layers 52 and 53 constitutes a part of the insulating layer 50 in FIG. 1 together with an insulating layer 51 described below.

As described above, the stacked body LM is divided in the Y direction by the plurality of plate-like contacts LI. That is, the plate-like contacts LI are each arranged in the Y direction and extend in the stacking direction of the stacked body LM and in a direction along the X direction.

As described above, the plate-like contacts LI continuously extend in the stacked body LM from one end portion to the other end portion of the stacked body LM in the X direction. In addition, the plate-like contacts LI penetrate the stacked body LM and the upper source line DSLb and reach the intermediate source line BSL in the memory region MR.

In addition, the plate-like contacts LI have, for example, a tapered shape in which the width in the Y direction decreases from the upper end portion toward the lower end portion. Alternatively, the plate-like contacts LI have, for example, a bowing shape in which the width in the Y direction is maximized at a predetermined position between the upper end portion and the lower end portion.

Each of the plate-like contacts LI includes an insulating layer 54 and a conductive layer 24. The insulating layer 54 is, for example, a silicon oxide layer or the like. The conductive layer 24 is, for example, a tungsten layer or a conductive polysilicon layer.

The insulating layer 54 covers the side walls of the plate-like contact LI facing each other in the Y direction. The conductive layer 24 is loaded inside the insulating layer 54, and electrically connected to the source line SL including the intermediate source line BSL. In addition, the upper end portion of the conductive layer 24 is connected to the upper layer wiring via a plug or the like at a position different from the cross section of FIG. 2A. Thus, the plate-like contact LI functions as a source line contact.

However, instead of the plate-like contact LI, a plate-like member filled with the insulating layer may penetrate the stacked body LM and extend in the direction along the X direction, thereby dividing the stacked body LM in the Y direction. In this case, the plate-like contact does not have a function as a source line contact.

Between the plate-like contacts LI adjacent in the Y direction, the plurality of separation layers SHE penetrating the upper layer portion of the stacked body LMb and extending in the direction along the X direction is disposed. These separation layers SHE are insulating layers 56 such as silicon oxide layers that penetrate the select gate lines SGD0 and SGD1 and reach the insulating layer OL immediately below the select gate line SGD1.

In other words, these separation layers SHE penetrating the upper layer portion of the stacked body LMb extend between the plate-like contacts LI in the X direction between the memory region MR and a part of the staircase regions SR, so that the upper layer portion of the stacked body LMb is partitioned into the select gate lines SGD0 and SGD1 described above.

In the memory region MR, the plurality of pillars PL penetrating the stacked body LM, the upper source line DSLb, and the intermediate source line BSL and reaching the lower source line DSLa is dispersedly disposed.

The plurality of pillars PL is disposed, for example, in a staggered manner when viewed from the stacking direction of the stacked body LM. Each pillar PL has, for example, a circular shape, an elliptical shape, an oblong shape (oval shape), or the like as a cross-sectional shape in a direction along the layering direction of the stacked body LM, that is, in a direction along the XY plane.

In addition, each of the pillars PL has a tapered shape in which the diameter and the cross-sectional area decrease from the upper layer side toward the lower layer side in a portion penetrating the stacked body LMa and a portion penetrating the stacked body LMb. Alternatively, each of the pillars PL has, for example, a bowing shape in which the diameter and the cross-sectional area are maximized at a predetermined position between the upper layer side and the lower layer side in a portion penetrating the stacked body LMa and a portion penetrating the stacked body LMb.

Each of the plurality of pillars PL includes a memory layer ME extending in the stacked body LM in the stacking direction, a channel layer CN penetrating the stacked body LM and connected to the intermediate source line BSL, a cap layer CP covering the upper surface of the channel layer CN, and a core layer CR serving as a core material of the pillar PL.

As illustrated in FIGS. 2B and 2C, the memory layer ME has a multilayer structure in which a block insulating layer BK, a charge storage layer CT, and a tunnel insulating layer TN are stacked in this order from the outer peripheral side of the pillar PL. More specifically, the memory layer ME is disposed on a side surface of the pillar PL except for the depth position of the intermediate source line BSL. In addition, the memory layer ME is also disposed on the bottom surface of the pillar PL reaching the depth of the lower source line DSLa.

The channel layer CN penetrates the stacked body LM, the upper source line DSLb, and the intermediate source line BSL inside the memory layer ME and reaches the depth of the lower source line DSLa. More specifically, the channel layer CN is disposed on the side surface and the bottom surface of the pillar PL via the memory layer ME. However, a part of the channel layer CN is, on a side surface, in contact with the intermediate source line BSL, so that the channel layer CN is electrically connected to the source line SL including the intermediate source line BSL. The core layer CR is loaded further inside the channel layer CN.

In addition, each of the plurality of pillars PL has the cap layer CP at the upper end portion. The cap layer CP is disposed at the upper end portion of the pillar PL so as to cover at least the upper end portion of the channel layer CN, and is connected to the channel layer CN. In addition, the cap layer CP is connected to a bit line BL disposed in the insulating layer 53 via plugs CH disposed in the insulating layer 52. The bit line BL extends above the stacked body LM in the direction along the Y direction so as to intersect with the lead-out direction of the word lines WL.

Note that, in FIG. 2A, the plugs CH are connected only to three pillars PL that penetrate the select gate lines SGD separated into three and are electrically connected to the bit line BL illustrated in FIG. 2A among the six pillars PL. The other pillars PL are connected to another bit line BL extending in the direction along the Y direction in parallel with the bit line BL illustrated in FIG. 2A via plugs CH, which are not illustrated in FIG. 2A, at positions different from the cross section illustrated in FIG. 2A.

The block insulating layer BK and the tunnel insulating layer TN of the memory layer ME, and the core layer CR are, for example, silicon oxide layers or the like. The charge storage layer CT of the memory layer ME is, for example, a silicon nitride layer or the like. The channel layer CN and the cap layer CP are semiconductor layers such as a polysilicon layer or an amorphous silicon layer.

As illustrated in FIG. 2C, with the above configuration, a memory cell MC is formed in each portion facing the individual word lines WL on the side surface of the pillar PL. When a predetermined voltage is applied from the word line WL, data is written to and read from the memory cell MC.

In addition, as illustrated in FIG. 2B, a select gate STD is formed in a portion where the side surface of the pillar PL faces the select gate lines SGD0 and SGD1 above the word lines WL. In addition, a select gate STS is formed in a portion where the side surface of the pillar PL faces the select gate lines SGS0 and SGS1 below the word lines WL.

When predetermined voltages are applied from the select gate lines SGD and SGS, the select gates STD and STS are turned on or off, and the memory cells MC of the pillar PL to which the select gates STD and STS belong can be brought into a selected state or a non-selected state.

As illustrated in FIG. 2D, the staircase region SR has staircase portions SP in which the plurality of word lines WL and the select gate lines SGD and SGS are processed in a staircase shape. The staircase portions SP illustrated in FIG. 2D are portions of the staircase region SR divided into the plurality of block regions BLK where the contacts CC are disposed and that have a function of leading out the word lines WL or the like.

The staircase portions SP are covered with the insulating layer 51. The insulating layer 51 reaches, for example, the height position of the uppermost layer of the stacked body LM, and the insulating layers 52 and 53 also cover the upper surface of the insulating layer 51. As described above, the insulating layer 51 also constitutes a part of the insulating layer 50 in FIG. 1.

In addition, in the staircase region SR, the source line SL includes an intermediate insulating layer SCO interposed between the upper source line DSLb and the lower source line DSLa instead of the intermediate source line BSL. The intermediate insulating layer SCO is, for example, a silicon oxide layer or the like.

Therefore, in the staircase region SR, the plate-like contact LI penetrates the insulating layer 51, the stacked body LM, and the upper source line DSLb, and reaches the intermediate insulating layer SCO.

A stopper layer STP is disposed above portions of the staircase portions SP where the word lines WL and the select gate lines SGS in the stacked body LMa are processed in a staircase shape via a spacer layer SPC covering these portions.

The spacer layer SPC includes a plurality of terrace portions and a step portion connecting the terrace portions in the stacking direction. The terrace portions and the step portion are provided corresponding to, for example, the terrace portion of each insulating layer OL included in the stacked body LMa and the step portion formed by the word line WL and the insulating layer OL or the select gate line SGS and the insulating layer OL. As a result, the spacer layer SPC is disposed along the shape of the plurality of word lines WL or the like processed in a staircase shape.

However, the terrace portions and the step portion of the staircase portion SP of the stacked body LMa and the terrace portions and the step portion of the spacer layer SPC may not correspond one-to-one. That is, the number of steps of the spacer layer SPC may be smaller than the number of steps of the staircase portion SP of the stacked body LMa. Even in this case, the spacer layer SPC is disposed substantially along the shape of the plurality of word lines WL or the like processed in a staircase shape. Alternatively, the spacer layer SPC may not have a step, but may have a substantially flat shape.

The spacer layer SPC is configured to include the same material as the insulating layer 51, and that is, for example, a silicon oxide layer or the like.

The stopper layer STP is disposed so as to cover the upper surface of the spacer layer SPC. When the spacer layer SPC has a staircase shape, the stopper layer STP also has a staircase shape along at least a part of the shape of the plurality of word lines WL or the like processed in a staircase shape. The stopper layer STP is configured to include a material different from that of the insulating layer 51, and that is, for example, a tungsten layer. In addition, the thickness of the stopper layer STP is preferably more than the thickness of each of the plurality of word lines WL or the like and less than twice the thickness of each of the word lines WL or the like.

Each contact CC of the staircase portion SP penetrates the insulating layer 51 or the like and is connected to the word line WL or the select gate line SGD or SGS immediately below the insulating layer OL constituting each step of the staircase portion SP.

Among the plurality of contacts CC, the contact CC connected to any one of the plurality of word lines WL and the select gate lines SGS included in the stacked body LMa penetrates the stopper layer STP and the spacer layer SPC and reaches a connection target word line WL or the like.

On the other hand, the stopper layer STP and the spacer layer SPC are not disposed at the disposition positions of the contacts CC connected to any of the plurality of word lines WL and the select gate lines SGD included in the stacked body LMb. Therefore, these contacts CC extend in the insulating layer 51 and reach the connection target word line or the like without penetrating the stopper layer STP and the spacer layer SPC.

Each contact CC has, for example, a tapered shape in which a diameter and a cross-sectional area decrease from the upper end portion toward the lower end portion. Alternatively, the contact CC has, for example, a bowing shape in which the diameter and the cross-sectional area are maximized at a predetermined position between the upper end portion and the lower end portion.

In addition, the contact CC includes an insulating layer 55 covering the outer periphery of the contact CC, and a conductive layer 25 such as a tungsten layer or a copper layer loaded inside the insulating layer 55.

The insulating layer 55 is a liner layer of the contact CC. The insulating layer 55 preferably has a thickness of, for example, 1.5 times or more, more preferably twice or more the thickness of each of the plurality of word lines WL or the like. As a result, the withstand voltage between the contacts CC penetrating the conductive stopper layer STP such as a tungsten layer is improved. The conductive layer 25 is a core layer serving as a core material of the contact CC, and is connected to upper layer wiring MX disposed in the insulating layer 53 via a plug V0 disposed in the insulating layer 52. The upper layer wiring MX is electrically connected to the peripheral circuits CBA (see FIG. 1) described above.

With such a configuration, the word lines WL of the layers and the select gate lines SGD and SGS of the upper and lower layers of the word lines WL can be electrically lead out from one end side or the other end side of the stacked body LM in the X direction. That is, with the above configuration, a predetermined voltage is applied from the peripheral circuit CBA to the memory cell MC via the upper layer wiring MX, the contact CC, the word line WL, and the like, and the memory cell MC can be operated as a storage element.

### (Method for Manufacturing Semiconductor Memory Device)

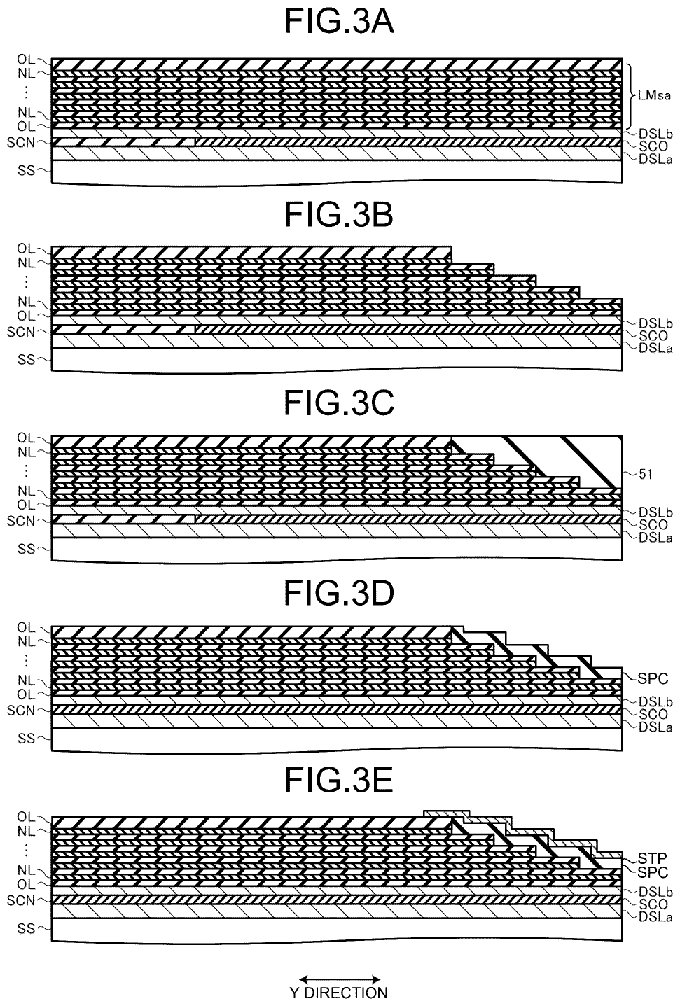

Next, a method for manufacturing the semiconductor memory device 1 of the embodiment will be described with reference to FIGS. 3A to 11C. FIGS. 3A to 11C are views sequentially illustrating a part of a procedure of a method for manufacturing the semiconductor memory device 1 according to the embodiment.

First, FIGS. 3A to 3E illustrate a stacked body LMsa, which is a lower layer portion of the stacked body LM before the word lines WL are formed, and a state where various configurations are formed in the stacked body LMsa.

FIGS. 3A to 3E are cross-sectional views along the X direction of a region that becomes the memory region MR and the staircase region SR later.

As illustrated in FIG. 3A, the lower source line DSLa, an intermediate sacrificial layer SCN or the intermediate insulating layer SCO, and the upper source line DSLb are formed in this order on a support substrate SS.

As the support substrate SS, a semiconductor substrate such as a silicon substrate, an insulating substrate such as a ceramic substrate, a conductive substrate, or the like can be used. The insulating layer 60 (see FIG. 2 or the like) described above may be formed on the upper surface side of the support substrate SS.

The intermediate sacrificial layer SCN is formed in a region on the support substrate SS to be the memory region MR later, and the intermediate insulating layer SCO is formed in a region on the support substrate SS to be the staircase region SR later. The intermediate sacrificial layer SCN is, for example, a silicon nitride layer or the like, and is a layer that is replaced with a polysilicon layer or the like later and becomes the intermediate source line BSL. As described above, the intermediate insulating layer SCO is, for example, a silicon oxide layer or the like.

In addition, the stacked body LMsa in which a plurality of insulating layers NL and the plurality of insulating layers OL are alternately stacked one by one is formed on the upper source line DSLb. The insulating layers NL are, for example, silicon nitride layers or the like, and function as sacrificial layers that are later replaced with conductive materials and become the word lines WL or the select gate lines SGS.

As illustrated in FIG. 3B, the insulating layers NL and the insulating layers OL are processed into a staircase shape in a partial region of the stacked body LMsa. Such processing can be performed by repeating slimming of a mask pattern such as a photoresist layer and etching of the insulating layers NL and the insulating layers OL of the stacked body LMsa a plurality of times.

That is, a mask pattern is formed on the upper surface of the stacked body LMsa, and, for example, the insulating layer NL and the insulating layer OL in an exposed portion are etched away one by one. In addition, an end portion of the mask pattern is retracted by treatment with oxygen plasma or the like to newly expose the upper surface of the stacked body LMsa, and the insulating layer NL and the insulating layer OL are further etched away one by one. By repeating such treatment a plurality of times, the staircase shape described above is formed.

As illustrated in FIG. 3C, the insulating layer 51 covering the stair part and reaching the height of the upper surface of the stacked body LMsa is formed. The insulating layer 51 is also formed in an outer region of the stacked body LMsa.

As illustrated in FIG. 3D, the insulating layer 51 is processed in a staircase shape along a portion where the insulating layers NL and OL of the stacked body LMsa are processed in a staircase shape to form the spacer layer SPC.

As described above, in the spacer layer SPC, the terrace portions and the step portions may be formed so as to correspond one-to-one to the terrace portions and the step portions formed by the insulating layers NL and OL of the stacked body LMsa, and the terrace portions and the step portions may be formed so as to have a smaller number of steps than the staircase shape by the insulating layers NL and OL of the stacked body LMsa. The spacer layer SPC may have a substantially flat shape by not processing the insulating layer 51 or by processing the insulating layer 51 to have a substantially flat surface.

As illustrated in FIG. 3E, the stopper layer STP covering the upper surface of the spacer layer SPC is formed. The stopper layer STP is preferably formed to have a thickness more than the thickness of each of the plurality of word lines WL or the like and less than twice the thickness of each of the word lines WL or the like.

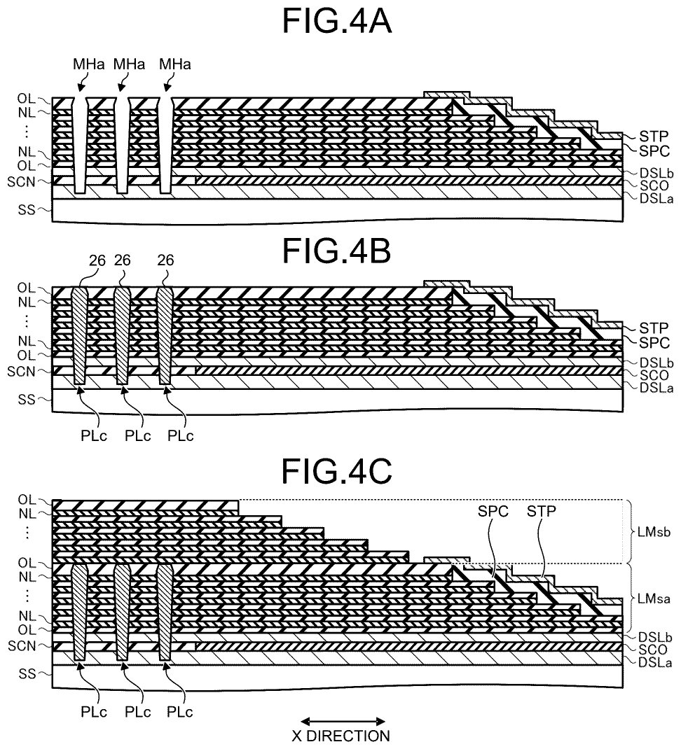

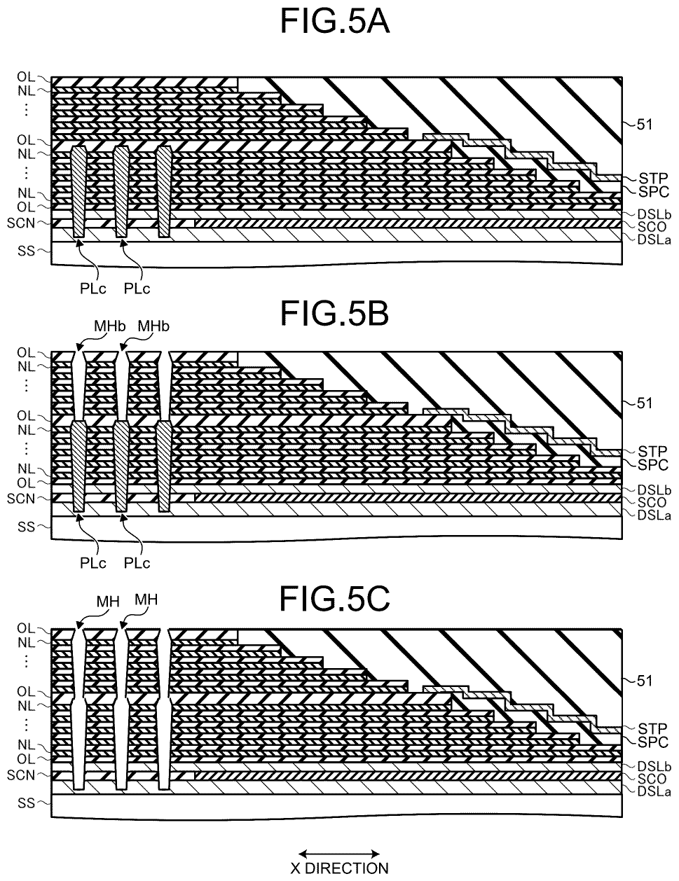

Next, FIGS. 4A to 5C illustrate a state where a stacked body LMsb, which is an upper layer portion of the stacked body LM before the word lines WL are formed, is formed and various configurations are formed in the stacked bodies LMsa and LMsb.

Similarly to FIGS. 3A to 3E, FIGS. 4A to 5C are cross-sectional views along the X direction of a region that becomes the memory region MR and the staircase region SR later.

As illustrated in FIG. 4A, a plurality of memory holes MHa extending through the stacked body LMsa in the stacking direction is formed. The memory holes MHa are portions that later become lower structures of the pillars PL. The plurality of memory holes MHa is disposed in a region that later becomes the memory region MR, penetrates the stacked body LMsa, the upper source line DSLb, and the intermediate sacrificial layer SCN, and reaches the lower source line DSLa.

As illustrated in FIG. 4B, the memory holes MHa are filled with sacrificial layers 26 such as amorphous silicon layers or CVD-carbon layers. As a result, in a region that later becomes the memory region MR, pillars PLc in which the plurality of memory holes MHa is filled with the sacrificial layers 26 are formed.

As illustrated in FIG. 4C, the stacked body LMsb that covers the stacked body LMsa including a portion processed in a staircase shape and in which the plurality of insulating layers NL and the plurality of insulating layers OL are alternately stacked one by one is formed. The insulating layers NL of the stacked body LMsb are later replaced with conductive layers and become the word lines WL or the select gate lines SGD.

In addition, the insulating layers NL and the insulating layers OL are processed into a staircase shape in a partial region of the stacked body LMsb. Similarly to the treatment illustrated in FIG. 3B described above, such processing can be performed by repeating slimming of a mask pattern such as a photoresist layer and etching of the insulating layers NL and the insulating layers OL of the stacked body LMsb a plurality of times.

At this time, the uppermost step of the stair part formed in the stacked body LMsa and the lowermost step of the stair part formed in the stacked body LMsb are brought close to each other so that they are formed continuously from the lower layer side of the stacked body LMsa to the upper layer side of the stacked body LMsb.

As illustrated in FIG. 5A, the insulating layer 51 covering the upper surface of the stopper layer STP and the stair part newly formed in the stacked body LMsb and reaching the height of the upper surface of the stacked body LMsb is formed. The insulating layer 51 is also formed in an outer region of the stacked bodies LMsa and LMsb. As a result, the insulating layer 51 in which the stopper layer STP is partially interposed is formed.

As illustrated in FIG. 5B, a plurality of memory holes MHb extending through the stacked body LMsb in the stacking direction is formed. The memory holes MHb are portions that later become upper structures of the pillars PL. The plurality of memory holes MHb is disposed in a region that later becomes the memory region MR, penetrates the stacked body LMsb, and reaches the upper end portions of the pillars PLC formed in the stacked body LMsa.

As illustrated in FIG. 5C, the sacrificial layers 26 are removed from the pillars PLc at the bottoms of the memory holes MHb. As a result, the memory holes MHa are opened at the bottoms of the plurality of memory holes MHb, and a plurality of memory holes MH penetrating the stacked bodies LMsb and LMsa, the upper source line DSLb, and the intermediate sacrificial layer SCN and reaching the lower source line DSLa is formed.

Note that, in a case where the sacrificial layers 26 loaded in the pillars PLc are CVD-carbon layers or the like, the sacrificial layers 26 can be collectively removed from these pillars PLC when the mask pattern or the like used in the treatment of FIG. 5B described above is removed by ashing or the like using oxygen plasma.

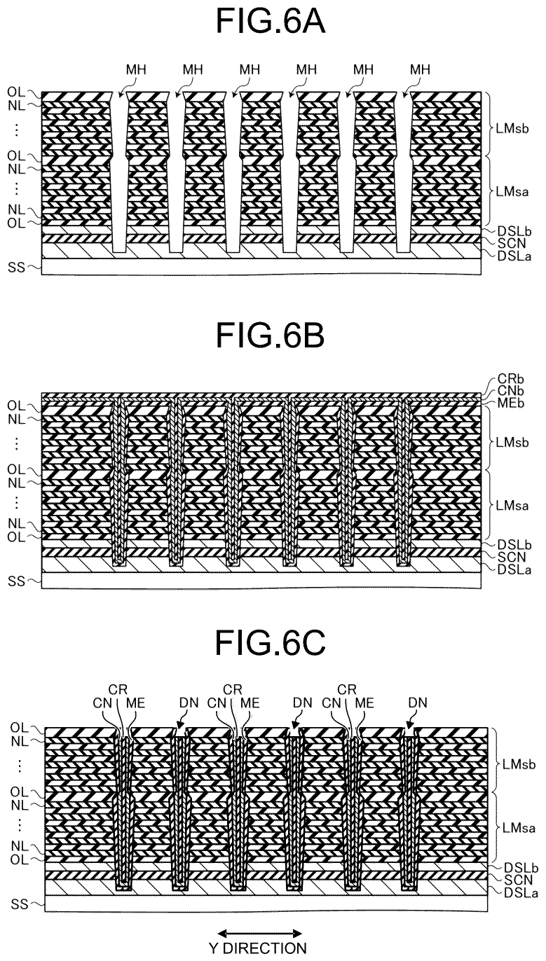

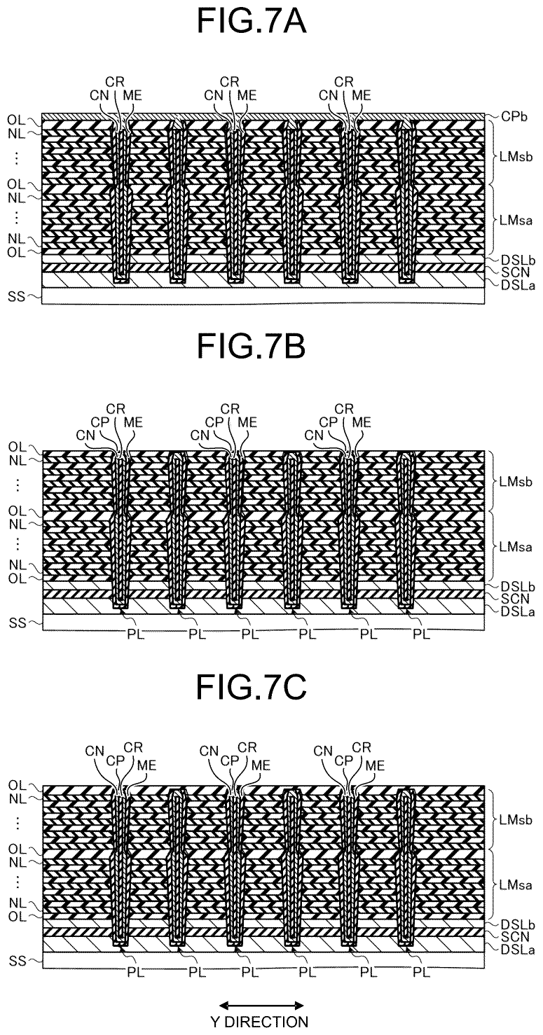

Next, a state where the pillars PL are formed by forming multilayer structures in the memory holes MH will be described with reference to FIGS. 6A to 7C. FIGS. 6A to 7C are cross-sectional views along the Y direction of a region that becomes the memory region MR later.

As illustrated in FIG. 6A, the plurality of memory holes MH is formed in a region that later becomes the memory region MR.

As illustrated in FIG. 6B, a multilayer insulating layer MEb, a semiconductor layer CNb, and an insulating layer CRb are formed in this order in the memory holes MH. As a result, the multilayer insulating layer MEb and the semiconductor layer CNb are disposed on the side surfaces of the memory holes MH and the bottom surfaces where the lower source line DSLa is exposed, and the insulating layer CRb is loaded in central portions of the memory holes MH.

The multilayer insulating layer MEb is an insulating layer having a multilayer structure that becomes the memory layer ME later. The semiconductor layer CNb is a layer that becomes the channel layer CN later. The insulating layer CRb is a silicon oxide layer or the like that becomes the core layer CR later.

The multilayer insulating layer MEb, the semiconductor layer CNb, and the insulating layer CRb are also formed in this order on the upper surface of the stacked body LMsb.

As illustrated in FIG. 6C, in a region that later becomes the memory region MR, the insulating layer CRb, the semiconductor layer CNb, and the multilayer insulating layer MEb are sequentially etched back to be removed from the upper surface of the stacked body LMsb, and recesses DN from which the insulating layer CRb and the semiconductor layer CNb are removed are formed at the upper end portions of the memory holes MH.

As a result, the memory layers ME, the channel layers CN, and the core layers CR are formed in the memory holes MH in this order from the outer peripheral side.

As illustrated in FIG. 7A, in a region that later becomes the memory region MR, a semiconductor layer CPb is formed in the recesses DN at the upper end portions of the memory holes MH. The semiconductor layer CPb is a layer that becomes the cap layers CP later. The semiconductor layer CPb is also formed on the upper surface of the stacked body LMsb.

As illustrated in FIG. 7B, in a region that later becomes the memory region MR, the semiconductor layer CPb on the upper surface of the stacked body LMsb is removed by CMP or the like, and the cap layers CP are formed at the upper end portions of the memory holes MH. In addition, the uppermost insulating layer OL of the stacked body LMsb thinned by CMP or the like is thickened.

As a result, as illustrated in FIG. 7C, the pillars PL in which the cap layers CP are embedded in the uppermost insulating layer OL are formed. However, at this time point, the memory layer ME covers the entire side wall of the pillar PL, and a part of the side surface of the channel layer CN is not in a state of being exposed from the memory layer ME.

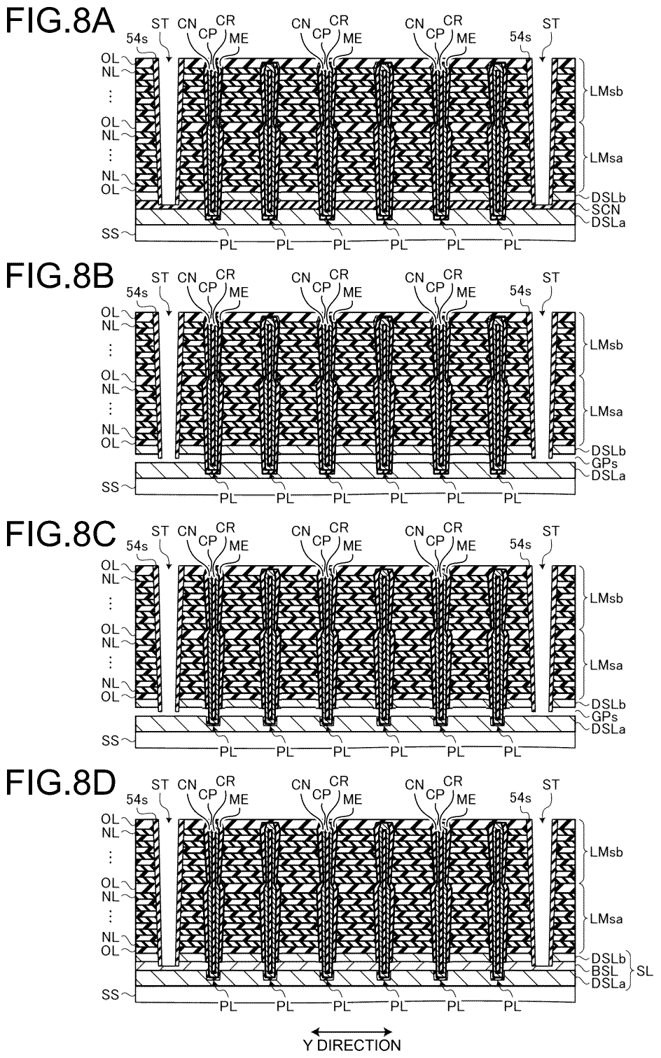

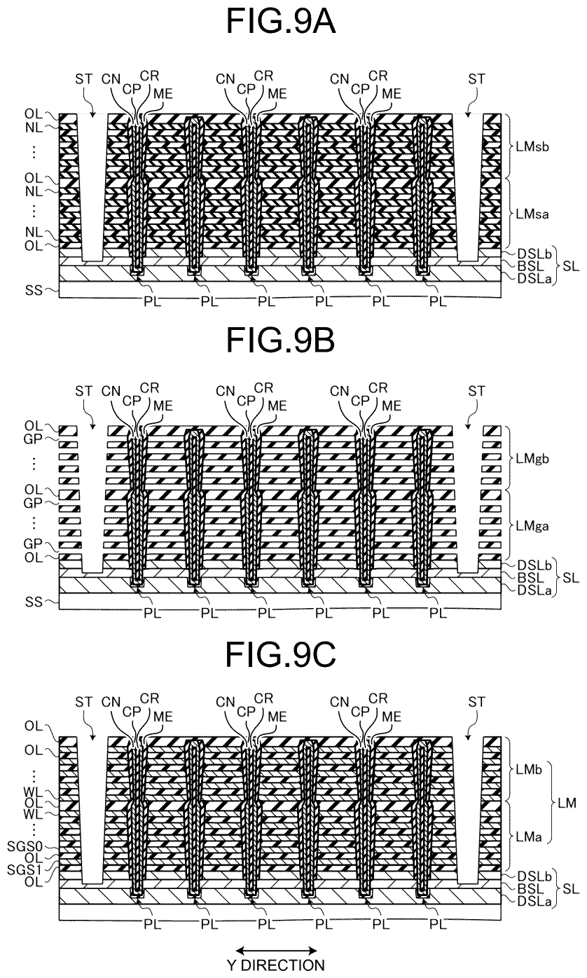

Next, a state where the source line SL and the word line WL are formed will be described with reference to FIGS. 8A to 9C. Similarly to FIGS. 6A to 7C, FIGS. 8A to 9C are cross-sectional views along the Y direction of a region that becomes the memory region MR later.

As illustrated in FIG. 8A, slits ST that penetrate the stacked bodies LMsb and LMsa and the upper source line DSLb and reach the intermediate sacrificial layer SCN are formed. In addition, insulating layers 54s are formed on the side walls of the slits ST facing each other in the Y direction.

The slit ST has a Y-direction longitudinal cross section of a tapered shape or a bowing shape, and also extends in the stacked bodies LMsa and LMsb in the direction along the X direction. Accordingly, in the staircase region SR, which is not illustrated, the lower end portion of the slit ST reaches the intermediate insulating layer SCO.

As illustrated in FIG. 8B, a removal liquid of the intermediate sacrificial layer SCN such as hot phosphoric acid is caused to flow through the slits ST whose side walls are protected by the insulating layers 54s, and the intermediate sacrificial layer SCN sandwiched between the lower source line DSLa and the upper source line DSLb is removed.

As a result, a gap layer GPs is formed between the lower source line DSLa and the upper source line DSLb. In addition, a part of the memory layer ME in the outer peripheral portions of the pillars PL is exposed in the gap layer GPs.

At this time, since the side walls of the slits ST are protected by the insulating layers 54s, it is suppressed that the insulating layers NL in the stacked bodies LMsa and LMsb are also removed. In addition, in the staircase region SR, which is not illustrated, there is no intermediate sacrificial layer SCN between the lower source line DSLa and the upper source line DSLb, and the gap layer GPs is not formed.

As illustrated in FIG. 8C, a chemical liquid is caused to appropriately flow into the gap layer GPs through the slits ST, and the block insulating layer BK, the charge storage layer CT, and the tunnel insulating layer TN (see FIGS. 2B and 2C) of the memory layer ME exposed in the gap layer GPs are sequentially removed. As a result, the memory layers ME are removed from partial side walls of the pillars PL, and a part of the channel layers CN on the inner side is exposed in the gap layer GPS.

As illustrated in FIG. 8D, a source gas such as amorphous silicon is injected from the slits ST whose side walls are protected by the insulating layers 54s, and the gap layer GPs is filled with amorphous silicon or the like. In addition, the support substrate SS is heat-treated to polycrystallize the amorphous silicon loaded in the gap layer GPs, thereby forming the intermediate source line BSL containing polysilicon or the like.

As a result, a part of the channel layers CN of the pillars PL is connected to the source line SL on the side surfaces via the intermediate source line BSL.

At this time, in the staircase region SR, which is not illustrated, the gap layer GPs is not formed between the lower source line DSLa and the upper source line DSLb. In addition, the intermediate source line BSL is not formed.

As illustrated in FIG. 9A, the insulating layers 54s on the side walls of the slits ST are temporarily removed.

As illustrated in FIG. 9B, a removal liquid of the insulating layers NL such as, for example, hot phosphoric acid is caused to flow into the stacked bodies LMsa and LMsb from the slits ST to remove the insulating layers NL of the stacked bodies LMsa and LMsb. As a result, stacked bodies LMga and LMgb including a plurality of gap layers GP from which the insulating layers NL between the insulating layers OL are removed are formed.

The stacked bodies LMga and LMgb including the plurality of gap layers GP have a fragile structure. In a region that later becomes the memory region MR, the plurality of pillars PL supports such fragile stacked bodies LMga and LMgb.

Such a support structure of the pillars PL suppresses bending of the remaining insulating layers OL and distortion or collapse of the stacked bodies LMga and LMgb. In addition, in a region that later becomes the staircase region SR, the stopper layer STP suppresses bending of the insulating layers OL and distortion or collapse of the stacked bodies LMga and LMgb.

As illustrated in FIG. 9C, a source gas of a conductive material such as tungsten or molybdenum is injected from the slits ST into the stacked bodies LMga and LMgb, and the gap layers GP of the stacked bodies LMga and LMgb are filled with the conductive material to form the plurality of word lines WL and the like. As a result, the stacked body LM including stacked bodies LMa and LMb in which the plurality of word lines WL and the plurality of insulating layers OL are alternately stacked one by one is formed.

Note that the uppermost layer and the second conductive layer from the uppermost layer of the stacked body LMb are partitioned into a pattern of the plurality of select gate lines SGD by forming the separation layers SHE penetrating therethrough later.

As described above, the treatment of forming the intermediate source line BSL from the intermediate sacrificial layer SCN and the treatment of forming the word lines WL from the insulating layers NL are also referred to as replacement treatment.

Thereafter, the insulating layers 54 are formed on the side walls of the slits ST, and the insulating layers 54 are filled with the conductive layers 24 to form the plate-like contacts LI. However, the insulating layers 54 or the like may be loaded in the slits ST without forming the conductive layers 24 to form the plate-like members.

In addition, grooves penetrating one or a plurality of conductive layers including the uppermost conductive layer of the stacked body LMb are formed, and the insulating layers 56 are loaded in the grooves to form the separation layers SHE that partition these conductive layers into the pattern of the select gate lines SGD.

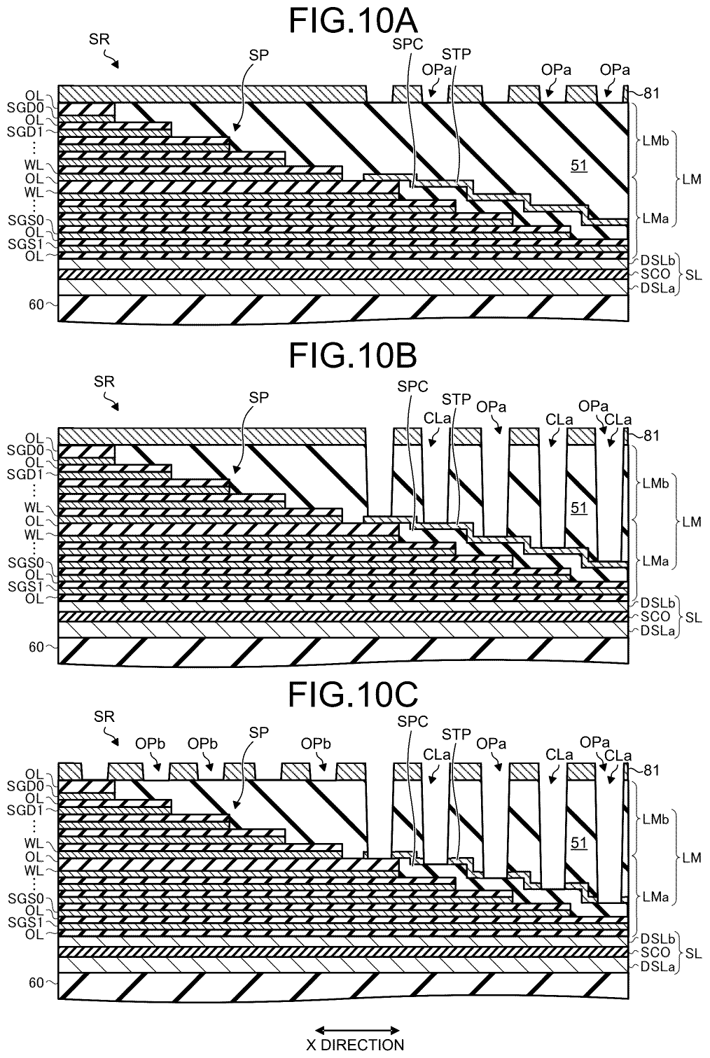

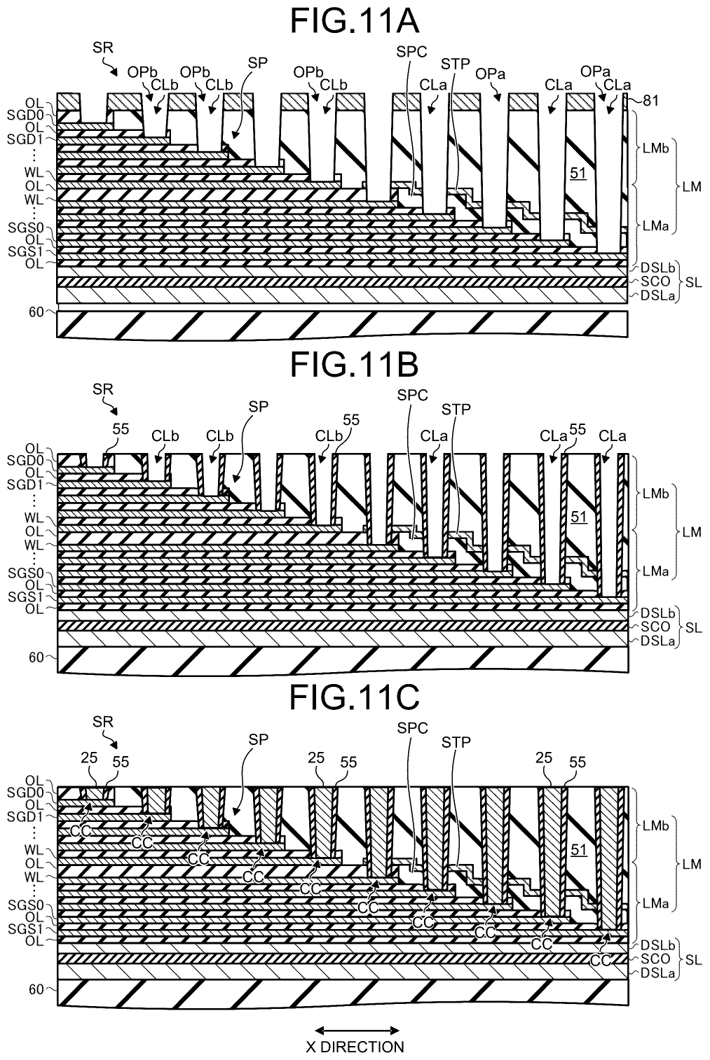

Next, a state where the plurality of contacts CC is formed in the staircase region SR will be described with reference to FIGS. 10A to 11C. FIGS. 10 and 11 are cross-sectional views of the staircase region SR along the X direction.

As illustrated in FIG. 10A, a mask pattern 81 that covers the upper surfaces of the insulating layer 51 and the stacked body LM is formed in the staircase region SR. The mask pattern 81 preferably contains, for example, the same type of material as the above-described stopper layer STP, and when the stopper layer STP is a tungsten layer or the like, the mask pattern 81 can also be a pattern of the tungsten layer. In addition, the mask pattern 81 has a plurality of openings OPa at positions overlapping, in the stacking direction, the portions where the word lines WL and the like of the stacked body LMa are processed in a staircase shape.

As illustrated in FIG. 10B, the insulating layer 51 covering the staircase portion SP is etched via such a mask pattern 81 to form a plurality of contact holes CLa penetrating the insulating layer 51 and reaching the stopper layer STP. By setting the stopper layer STP as a layer containing the same type of material as the mask pattern 81, selectivity with respect to the stopper layer STP can be obtained, and the stopper layer STP can function as an etch stopper. In addition, as described above, by setting the thickness of the stopper layer STP to be more than the thickness of the word lines WL or the like, for example, it is possible to more reliably suppress the contact holes CLa from penetrating the stopper layer STP.

As illustrated in FIG. 10C, a plurality of openings OPb is formed in the mask pattern 81 at positions overlapping, in the stacking direction, the portions where the word lines WL and the like of the stacked body LMb are processed in a staircase shape. At this time, the stopper layer STP exposed on the bottom surfaces of the plurality of contact holes CLa is also etched away, and the plurality of contact holes CLa is in a state of penetrating the stopper layer STP. At this time, as described above, by setting the thickness of the stopper layer STP to be less than twice the thickness of the word lines WL, for example, the contact holes CLa can more reliably penetrate the stopper layer STP.

As illustrated in FIG. 11A, the insulating layer 51 covering the staircase portion SP is etched via the mask pattern 81 in which the plurality of openings OPb is formed to form a plurality of contact holes CLb penetrating the insulating layer 51 and reaching the individual word lines WL and the like of the stacked body LMb. At this time, the plurality of contact holes CLa also reaches the individual word lines WL and the like of the stacked body LMa.

As illustrated in FIG. 11B, the insulating layers 55 that cover the side walls of the plurality of contact holes CLa and CLb are formed. At this time, for example, the insulating layer 55 can be formed so as to have a thickness of 1.5 times or more the thickness of each of the plurality of word lines WL and the like, and more preferably, the insulating layer 55 can be formed so as to have a thickness of twice or more. As a result, it is possible to maintain the withstand voltage between the individual contacts CC extending through the stopper layer STP, which is, for example, a conductive tungsten layer or the like.

As illustrated in FIG. 11C, a conductive material such as tungsten is loaded into the plurality of contact holes CLa and CLb on the side walls of which the insulating layers 55 are formed, and the conductive layers 25 to be core layers of the plurality of contact holes CLa and CLb are formed.

As described above, the plurality of contacts CC is formed in the staircase portion SP.

Thereafter, the insulating layer 52 is formed on the upper surface of the stacked body LM and the upper surface of the insulating layer 51 covering the staircase region SR, and the plugs V0 connected to the contacts CC are formed through the insulating layer 52. In addition, the plugs CH connected to the pillars PL are formed through the insulating layer 52. Further, the insulating layer 53 is formed on the insulating layer 52, and the upper layer wiring MX, the bit line BL, and the like connected to the plugs V0 and CH are formed. In addition, an electrode pad or the like for having electrical conduction with the peripheral circuits CBA is formed on the upper surface of the insulating layer 53.

Note that, for example, the plugs V0 and CH, the upper layer wiring MX, the bit line BL, and the like may be collectively formed by using a dual damascene method or the like.

In addition, the peripheral circuits CBA are formed on the semiconductor substrate SB separate from the support substrate SS on which the stacked body LM is formed, and are covered with the insulating layer 40. In the insulating layer 40, contacts, vias, wiring, or the like that lead the peripheral circuits CBA to the surface of the insulating layer 40 are formed and connected to the electrode pad or the like formed on the upper surface of the insulating layer 40.

Subsequently, the support substrate SS and the semiconductor substrate SB are bonded to each other by the insulating layers 50 and 40, and the electrode pads in the insulating layers 50 and 40 are connected. Thereafter, the support substrate SS is removed to expose the source line SL, and the electrode film EL is connected via the insulating layer 60 in which the plugs PG are formed.

Thus, the semiconductor memory device 1 of the embodiment is manufactured.

### Overview

A semiconductor memory device such as a three-dimensional nonvolatile memory is configured to be able to apply a voltage to a plurality of word lines or the like by stacking the plurality of word lines or the like, partially forming the word lines or the like in a staircase shape, and connecting contacts to their stair parts. These contacts are obtained, for example, by collectively forming a plurality of contact holes reaching each of the plurality of word lines or the like.

However, since the height difference between the plurality of word lines belonging to different layers of the stacked body is large, among the plurality of contact holes, a contact hole to be made to reach a word line or the like on the upper layer side may penetrate the reach target word line. When the contact hole penetrating the reach target word line reaches the lower word line, there is a possibility that these word lines are conducted via contacts formed thereafter.

Therefore, for example, it is conceivable that after the contact hole whose reach target is the word lines on the lower layer side reaches the height position above these word lines, the contact hole whose reach target is the word lines on the upper layer side is formed, and the contact hole whose reach target is the word lines on the lower layer side reaches the reach target word line by additional etching. At this time, for example, by adjusting the etching conditions and the aspect ratios of these contact holes, it is possible to perform control such that the etching of the contact hole whose reach target is the word lines on the lower layer side is temporarily stopped at the height position above the reach target word line.

As a result, it is possible to suppress excessive application of over-etching to the reach target word line at the time of forming the contact hole whose reach target is the word lines on the upper layer side. However, the adjustment of the etching conditions and the aspect ratios of the contact holes as described above requires precise control, and the margin of the etching conditions may be insufficient. In addition, when the etching is temporarily stopped at the height position above the reach target word line, the reach depths of these contact holes may vary.

With the semiconductor memory device 1 of the embodiment, the stopper layer STP is disposed at least at a position overlapping a portion where the plurality of word lines WL and the select gate lines SGS of the stacked body LMa are processed in a staircase shape in the stacking direction of the stacked body LM. In addition, the plurality of contacts CC connected to the plurality of word lines WL or the like of the stacked body LMa penetrates the stopper layer STP and extends in the stacking direction of the stacked body LM, and the plurality of contacts CC connected to the plurality of word lines WL or the like of the stacked body LMb extends in the stacking direction of the stacked body LM without penetrating the stopper layer STP. By disposing the stopper layer STP at the position of the contact CC on the lower layer side in this manner, it becomes easy to form the contact hole CLa in two stages, and it is possible to suppress the contact CC on the upper layer side from penetrating the connection target word line WL or the like.

With the semiconductor memory device 1 of the embodiment, each of the plurality of contacts CC connected to the plurality of word lines WL or the like of the stacked body LMa includes the insulating layer 55 covering the side wall of the conductive layer 25. As a result, even when the stopper layer STP is a layer having conductivity such as a tungsten layer, the withstand voltage between the plurality of contacts CC can be secured.

With the semiconductor memory device 1 of the embodiment, the thickness of the insulating layer 55 is 1.5 times or more, preferably twice or more the thickness of each of the plurality of word lines WL or the like. As a result, the withstand voltage between the plurality of contacts CC is more reliably maintained.

With the semiconductor memory device 1 of the embodiment, the stopper layer STP is disposed at a position away from the plate-like contacts LI in the Y direction. As described above, since the stopper layer STP is not in contact with the plate-like contacts LI, it is possible to prevent the electrical characteristics of the plate-like contacts LI from deteriorating due to the influence of the stopper layer STP.

By the method for manufacturing the semiconductor memory device 1 of the embodiment, the plurality of contact holes CLa extending from the height position above the stacked body LM at the position overlapping the staircase portion SP of the stacked body LMa in the stacking direction of the stacked body LM and reaching the stopper layer STP is formed via the mask pattern 81. As described above, since the etching is temporarily stopped by the stopper layer STP, it is possible to suppress variations in the reach depth of these contact holes CLa.

By the method for manufacturing the semiconductor memory device 1 of the embodiment, the plurality of openings OPb is formed at positions of the mask pattern 81 overlapping the staircase portion SP of the stacked body LMb in the stacking direction of the stacked body LM, and penetrates the stopper layer STP exposed on the bottom surfaces of the plurality of contact holes CLa whose reach target is the word lines WL or the like of the stacked body LMa.

As described above, since the opening of the mask pattern 81 for forming the contact holes CLb on the upper layer side and the removal of the stopper layer STP of the bottom surfaces of the contact holes CLa on the lower layer side are collectively performed, the number of processes for forming the contacts CC can be reduced.

By the method for manufacturing the semiconductor memory device 1 of the embodiment, the plurality of contact holes CLb extending from the height position above the stacked body LM at the position overlapping the staircase portion SP of the stacked body LMb in the stacking direction of the stacked body LM and reaching the portions where the plurality of word lines WL and the select gate lines SGD of the stacked body LMb are processed in a staircase shape is formed through the mask pattern 81 in which the plurality of openings OPb is formed, and the plurality of contact holes CLa is caused to reach the portions where the plurality of word lines WL and the select gate lines SGS of the stacked body LMa are processed in a staircase shape.

As described above, since the formation of the contact holes CLb on the upper layer side and the additional processing of the contact holes CLa on the lower layer side are collectively performed, the number of processes for forming the contacts CC can be reduced. In addition, when the additional etching is performed on the contact holes CLa on the lower layer side, it is possible to suppress excessive application of over-etching to the word lines WL of the stacked body LMb that are the reach targets of the contact holes CLb on the upper layer side.

Furthermore, since the contact holes CLa on the lower layer side are stopped above the reach target word lines WL or the like, there is no need to precisely adjust, for example, the etching conditions and the aspect ratios of these contact holes, and it is also possible to increase the margin of the etching conditions.

By the method for manufacturing the semiconductor memory device 1 of the embodiment, the spacer layer SPC including the plurality of terrace portions and the step portions connecting the terrace portions in the stacking direction of the stacked bodies LMsa and LMb and covering the stair part of the stacked body LMsa is formed along at least a part of the staircase shape of the plurality of insulating layers NL of the stacked body LMsa.

As described above, since the stopper layer STP is formed on the spacer layer SPC processed in a staircase shape, variations in distance between the stopper layer STP and the stair part of the stacked body LMsa are suppressed. As a result, the distances of the portions where additional etching is performed on the plurality of contact holes CLa can be made uniform, and the over-etching amount can be made uniform between the word lines WL on the lower layer side. Therefore, it is also possible to suppress excessive application of over-etching to the word lines WL on the upper layer side among the word lines WL on the lower layer side.

By the method for manufacturing the semiconductor memory device 1 of the embodiment, the stopper layer STP is formed to have a thickness more than the thickness of each of the plurality of word lines WL or the like and less than twice the thickness of each of the word lines WL or the like.

As described above, by setting the thickness of the stopper layer STP to be more than the thickness of the word lines WL, the etching of the plurality of contact holes CLa can be temporarily stopped by the stopper layer STP without penetrating the stopper layer STP. In addition, by setting the thickness of the stopper layer STP less than twice the thickness of the word lines WL, the stopper layer STP on the bottom surfaces of the contact holes CLa can be easily penetrated when the openings OPb are formed in the mask pattern 81.

By the method for manufacturing the semiconductor memory device 1 of the embodiment, the stopper layer STP is formed to contain the same type of material as the mask pattern 81. As a result, the plurality of contact holes CLa can be etched with sufficient selectivity with respect to the stopper layer STP.

Note that, in the above-described embodiment, the stopper layer STP is, for example, a tungsten layer. However, the stopper layer STP may be, for example, a tungsten silicon layer, a silicon layer, a metal oxide layer, or the like as long as it is a layer having etching selectivity at the time of etching the contact holes CLa. The silicon layer may be, for example, an amorphous silicon layer, a polysilicon layer, or the like. The metal oxide layer may be, for example, an aluminum oxide (Al₂O₃) layer or the like.

### Modification

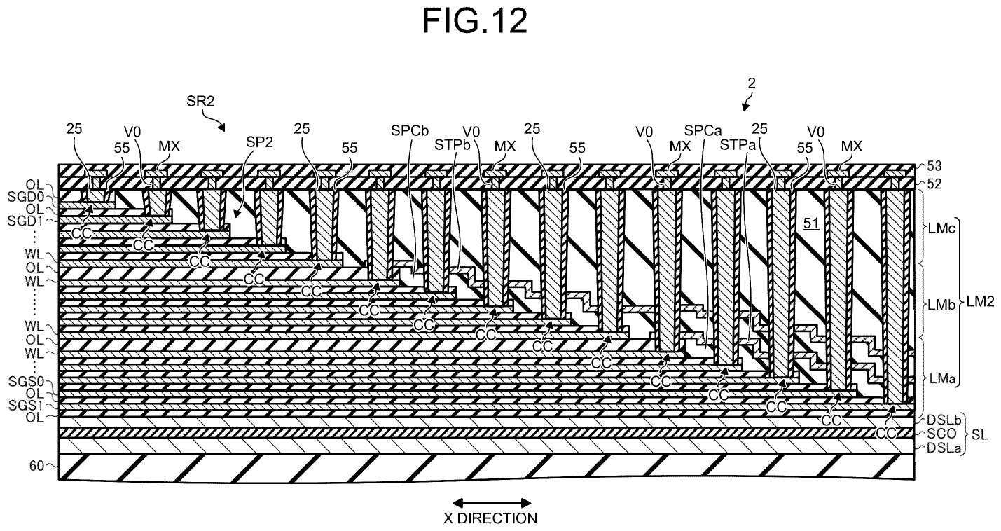

Next, a semiconductor memory device 2 of a modification of the embodiment will be described with reference to FIGS. 12 to 18B. The semiconductor memory device 2 of the modification is different from the semiconductor memory device of the above-described embodiment in that a stacked body LM2 having a three-tier structure is provided.

Note that, in the drawings described below, the same reference numerals are given to the same configurations as those of the above-described embodiment, and the description thereof may be omitted.

FIG. 12 is a cross-sectional view along an X direction illustrating an example of a configuration of a staircase region SR2 included in the semiconductor memory device 2 according to the modification of the embodiment. In FIG. 12, structures below the insulating layer 60 and above the insulating layer 53 described below are omitted.

As illustrated in FIG. 12, the semiconductor memory device 2 of the modification includes, for example, the stacked body LM2 having a three-tier structure in which three stacked bodies LMa, LMb, and LMc are stacked. These stacked bodies LMa, LMb, and LMc have a configuration in which the plurality of word lines WL and the plurality of insulating layers OL are alternately stacked one by one. In addition, these stacked bodies LMa, LMb, and LMc include staircase portions SP2 in which the plurality of word lines WL and the like are processed in a staircase shape, for example, in the staircase regions SR2 at both end portions in the X direction.

The stacked body LMa is disposed above the source line SL. The plurality of select gate lines SGS0 and SGS1 is disposed in this order from the upper layer side of the stacked body LMa via the insulating layers OL further below the lowermost word line WL of the stacked body LMa.

The stacked body LMb is disposed on the stacked body LMa. The stacked body LMb of the modification does not include the select gate lines SGD and SGS.

The stacked body LMc is disposed on the stacked body LMb. The plurality of select gate lines SGD0 and SGD1 is disposed in this order from the upper layer side of the stacked body LMc via the insulating layers OL further above the uppermost word line WL of the stacked body LMc.

In addition, the semiconductor memory device 2 of the modification includes a plurality of stopper layers STPa and STPb.

The stopper layer STPa is disposed above the portions of the staircase portions SP2 where the word lines WL and the select gate lines SGS in the stacked body LMa are processed in a staircase shape via a spacer layer SPCa covering these portions.

The spacer layer SPCa may have a plurality of terrace portions and step portions corresponding one-to-one to the terrace portions and the step portions formed by the word lines WL, the select gate lines SGS, and the insulating layers OL of the stacked body LMa, and may be configured to have a smaller number of steps than the staircase shape by the word lines WL and the like of the stacked body LMa. The spacer layer SPCa may have a substantially flat shape.

The stopper layer STPb is disposed at a height position above the stopper layer STPa. More specifically, the stopper layer STPb is disposed above portions of the staircase portions SP2 where the word lines WL and the select gate lines SGS in the stacked body LMa are processed in a staircase shape and portions of the staircase portions SP2 where the word lines WL in the stacked body LMb are processed into a staircase shape via a spacer layer SPCb covering these portions.

The spacer layer SPCb may have a plurality of terrace portions and step portions corresponding one-to-one to the terrace portions and the step portions formed by the word lines WL, the select gate lines SGS, and the insulating layers OL of the stacked bodies LMa and LMb, and may be configured to have a smaller number of steps than the staircase shape by the word lines WL and the like of the stacked bodies LMa and LMb. The spacer layer SPCb may have a substantially flat shape.

The spacer layers SPCa and SPCb are configured to include the same material as the insulating layer 51, and that is, for example, a silicon oxide layer or the like.

The stopper layers STPa and STPb are configured to include a material different from that of the insulating layer 51, and that is, for example, a tungsten layer. However, the stopper layers STPa and STPb may be silicon layers such as tungsten silicon layers, amorphous silicon or the like, or polysilicon layers, metal oxide layers such as aluminum oxide layers, or the like. The thickness of the stopper layers STPa and STPb is preferably more than the thickness of each of the plurality of word lines WL or the like and less than twice the thickness of each of the word lines WL or the like.

Among the plurality of contacts CC, the contacts CC connected to the word lines WL and the select gate lines SGS of the stacked body LMa penetrate the stopper layer STPa and the spacer layer SPCa and reach the connection target word line WL or the like.

Among the plurality of contacts CC, the contacts CC connected to the word lines WL of the stacked body LMb penetrate the stopper layer STPb and the spacer layer SPCb and reach the connection target word lines WL or the like.

Among the plurality of contacts CC, the contacts CC connected to the word lines WL and the select gate lines SGD of the stacked body LMc reach the connection target word lines WL or the like without penetrating any of the stopper layers STPa and STPb and the spacer layers SPCa and SPCb.

A method for manufacturing the semiconductor memory device 2 of the modification configured as described above will be described below.

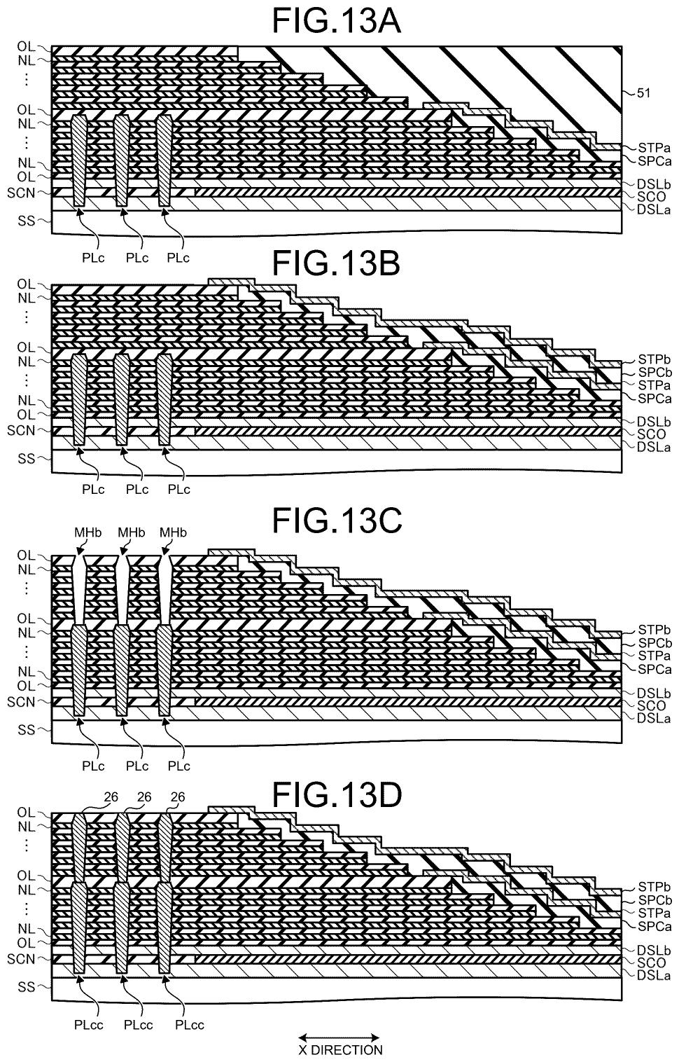

FIGS. 13A to 18B are views sequentially illustrating a part of a procedure of a method for manufacturing the semiconductor memory device 2 according to the modification of the embodiment. FIGS. 13A to 18B illustrate a method for forming mainly the staircase portions SP2 and the contacts CC of the semiconductor memory device 2.

FIGS. 13A to 15B illustrate a state where stacked bodies LMsb and LMsc before the word lines WL are formed are formed and various configurations are formed in the stacked bodies LMsb and LMsc. FIGS. 13A to 15B are cross-sectional views along the X direction of a region that becomes the memory region MR and the staircase region SR2 later.

In the cross-sectional view illustrated in FIG. 13A, a configuration substantially similar to that in the cross-sectional view illustrated in FIG. 5A of the above-described embodiment has already been formed. In FIG. 13A, the stopper layer STPa and the spacer layer SPCa corresponding to the stopper layer STP and the spacer layer SPC of FIG. 5A of the above-described embodiment have been formed, and these are covered with the insulating layer 51 reaching the height position of the stacked body LMsb. These configurations illustrated in FIG. 13A can be formed by treatment similar to the treatment illustrated in FIGS. 3 to 4 of the above-described embodiment.

As illustrated in FIG. 13B, the insulating layer 51 is processed in a staircase shape along the stopper layer STPa above the stacked body LMsa and along the portions where the insulating layers NL and OL of the stacked body LMsb are processed in a staircase shape, thereby forming the spacer layer SPCb, and further forming the stopper layer STPb covering the upper surface of the spacer layer SPCb.

As described above, in the spacer layer SPCb, the terrace portions and the step portions may be formed so as to correspond one-to-one to the terrace portions and the step portions of the stopper layer STPa above the stacked body LMsa and the terrace portions and the step portions formed by the insulating layers NL and OL of the stacked body LMsb, and the terrace portions and the step portions may be formed so as to have a smaller number of steps than the staircase shape of the stopper layer STPa or the staircase shape by the insulating layers NL and OL of the stacked body LMsa. The spacer layer SPCb may have a substantially flat shape by not processing the insulating layer 51 or by processing the insulating layer 51 to have a substantially flat surface.

As illustrated in FIG. 13C, a plurality of memory holes MHb extending through the stacked body LMsb in the stacking direction and reaching the upper end portions of the pillars PLC formed in the stacked body LMsa is formed.

As illustrated in FIG. 13D, the memory holes MHb are filled with sacrificial layers 26 such as amorphous silicon layers or CVD-carbon layers. As a result, in a region that later becomes the memory region MR, a plurality of pillars PLcc in which the plurality of memory holes MHb is filled with the sacrificial layers 26 and the pillars PLc described above are connected to the lower end portions is formed.

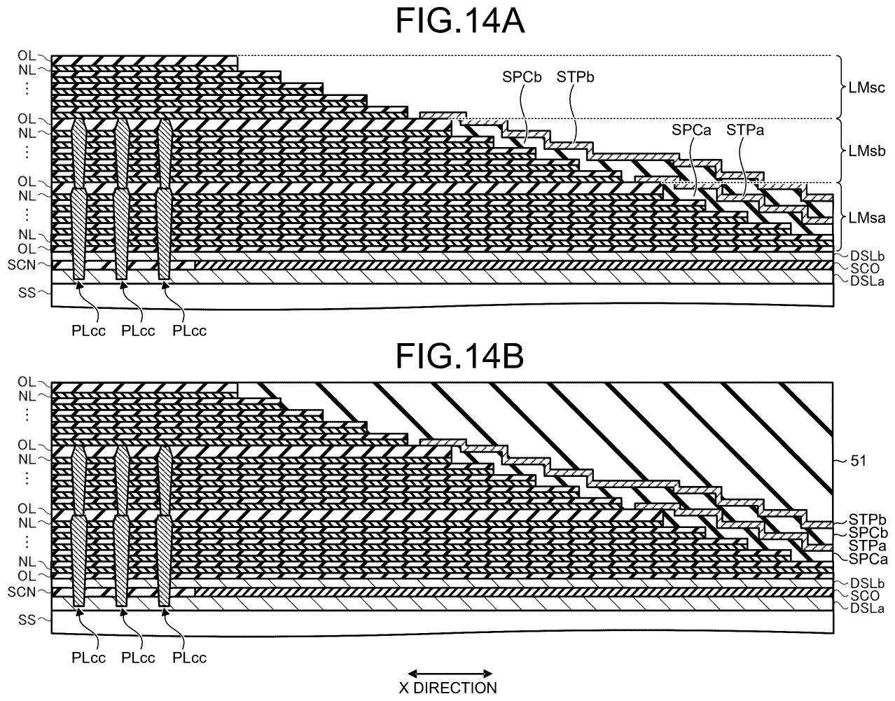

As illustrated in FIG. 14A, the stacked body LMsc is formed covering the portion processed in a staircase shape in the stacked body LMsa and the stacked body LMsb including the portion processed in a staircase shape and in which the plurality of insulating layers NL and the plurality of insulating layers OL are alternately stacked one by one. The insulating layers NL of the stacked body LMsc are later replaced with conductive layers and become the word lines WL or the select gate lines SGD.

In addition, the insulating layers NL and the insulating layers OL are processed into a staircase shape in a partial region of the stacked body LMsc. Similarly to the treatment illustrated in FIG. 3B of the above-described embodiment, such processing can be performed by repeating slimming of a mask pattern such as a photoresist layer and etching of the insulating layers NL and the insulating layers OL of the stacked body LMsc a plurality of times.

At this time, the uppermost step of the stair part formed in the stacked body LMsb and the lowermost step of the stair part formed in the stacked body LMsc are brought close to each other so that the staircase shape by the insulating layers NL and OL is formed continuously from the lower layer side of the stacked body LMsa to the upper layer side of the stacked body LMSC.

As illustrated in FIG. 14B, the insulating layer 51 covering the upper surface of the stopper layer STPb and the stair part newly formed in the stacked body LMsc and reaching the height of the upper surface of the stacked body LMsc is formed. The insulating layer 51 is also formed in an outer region of the stacked bodies LMsa, LMsb, and LMsc. As a result, the insulating layer 51 in which the stopper layers STPa and STPb are partially interposed is formed.

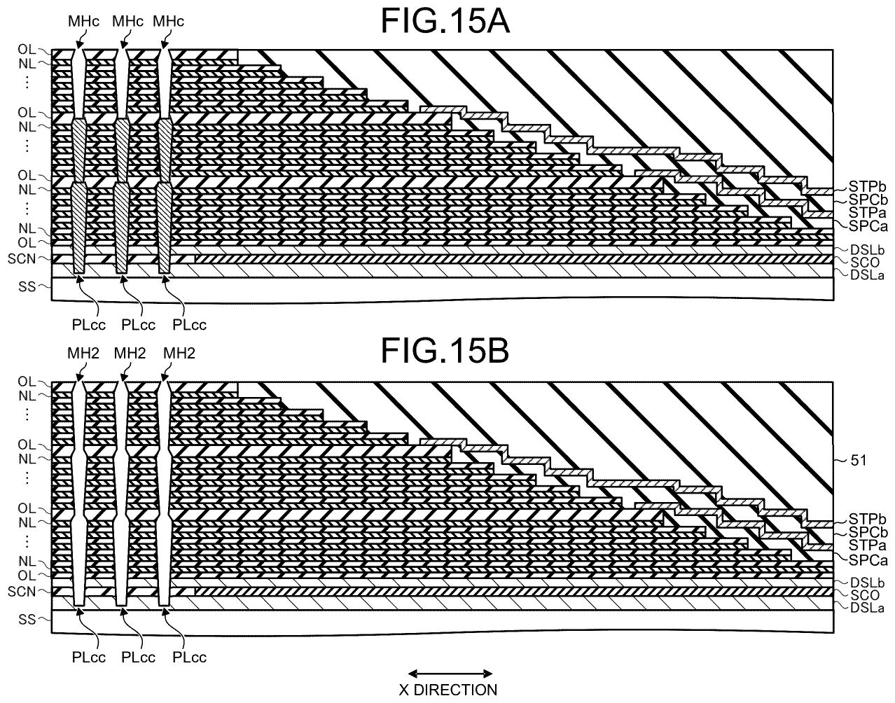

As illustrated in FIG. 15A, a plurality of memory holes MHc extending through the stacked body LMsc in the stacking direction and reaching the upper end portions of the pillars PLcc formed in the stacked bodies LMsa and LMsb is formed.

As illustrated in FIG. 15B, the sacrificial layers 26 are removed from the pillars PLcc at the bottoms of the memory holes MHc. As a result, the memory holes MHa and MHb are opened at the bottoms of the plurality of memory holes MHc, and a plurality of memory holes MH2 penetrating the stacked bodies LMsc, LMsb, and LMsa, the upper source line DSLb, and the intermediate sacrificial layer SCN and reaching the lower source line DSLa is formed.

Thereafter, the memory layer ME, the channel layer CN, and the core layer CR extending in the stacked bodies LMsc, LMsb, and LMsa are formed in the memory holes MH2, and the intermediate sacrificial layer SCN of the source line SL is further replaced to form the source line SL having the intermediate source line BSL and the plurality of pillars PL connected to the source line SL on the side surfaces of the channel layers CN is formed.

In addition, the insulating layers NL of the stacked bodies LMsa, LMsb, and LMsc are replaced with the conductive material by the replacement treatment, and the stacked bodies LMa, LMb, and LMc having the plurality of word lines WL and the select gate lines SGD and SGS are formed.

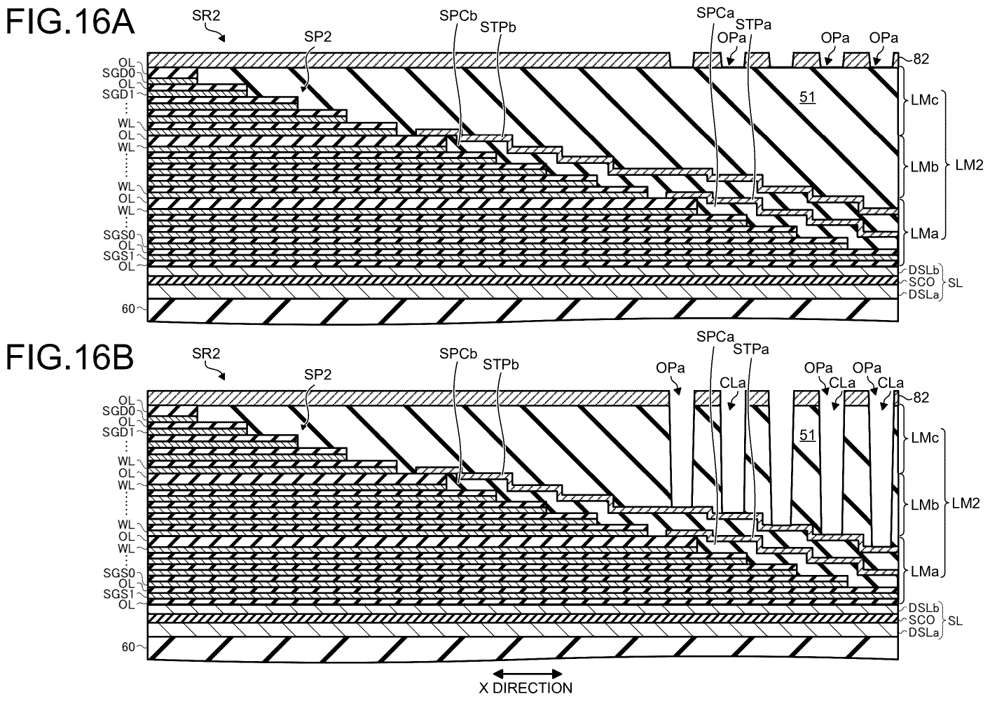

Next, a state where the plurality of contacts CC is formed in the staircase region SR2 will be described with reference to FIGS. 16A to 18B. FIGS. 16A to 18B are cross-sectional views of the staircase region SR2 along the X direction.

As illustrated in FIG. 16A, the staircase region SR2 includes, for example, the same type of material as the stopper layers STPa and STPb described above, and a mask pattern 82 having the plurality of openings OPa at positions overlapping, in the stacking direction, the portions where the word lines WL and the like of the stacked body LMa are processed in a staircase shape and covering the upper surface of the insulating layer 51 and the stacked body LM2 is formed.

As illustrated in FIG. 16B, the insulating layer 51 covering the staircase portion SP2 is etched via the mask pattern 82 to form the plurality of contact holes CLa penetrating the insulating layer 51 and reaching the stopper layer STPb.

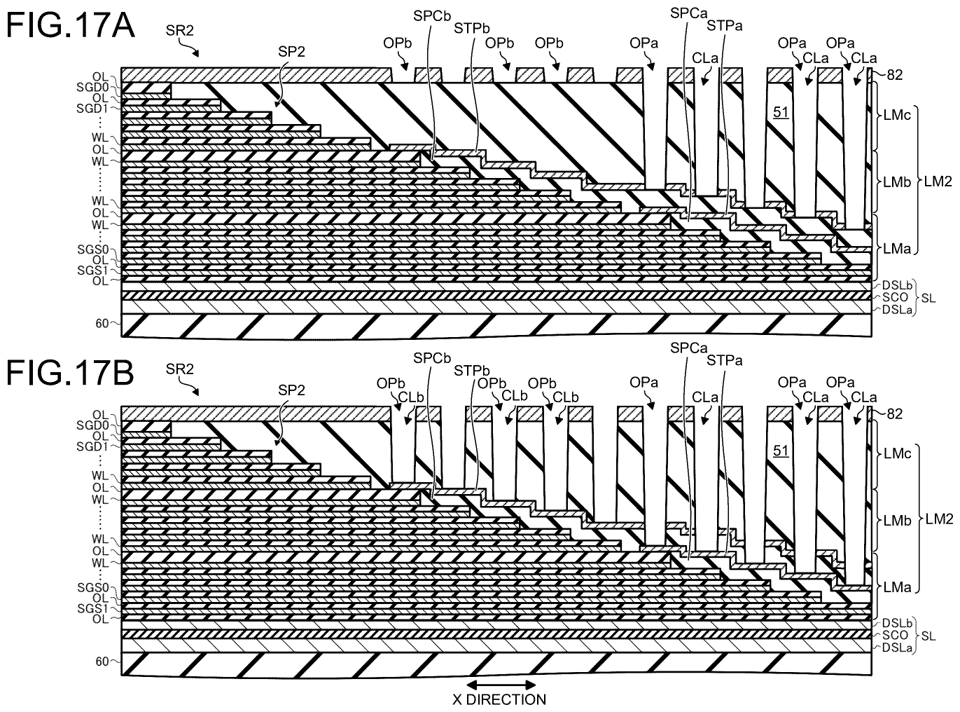

As illustrated in FIG. 17A, the plurality of openings OPb is formed in the mask pattern 82 at positions overlapping, in the stacking direction, the portions where the word lines WL and the like of the stacked body LMb are processed in a staircase shape. At this time, the stopper layer STPb exposed on the bottom surfaces of the plurality of contact holes CLa is also etched away, and the plurality of contact holes CLa is in a state of penetrating the stopper layer STPb.

As illustrated in FIG. 17B, the insulating layer 51 covering the staircase portion SP2 is etched via the mask pattern 82 in which the plurality of openings OPb is formed to form the plurality of contact holes CLb penetrating the insulating layer 51 and reaching the stopper layer STPb above the staircase portion SP2 of the stacked body LMb. At this time, the plurality of contact holes CLa also penetrates the spacer layer SPCb above the staircase portion SP2 of the stacked body LMa and reaches the stopper layer STPa.

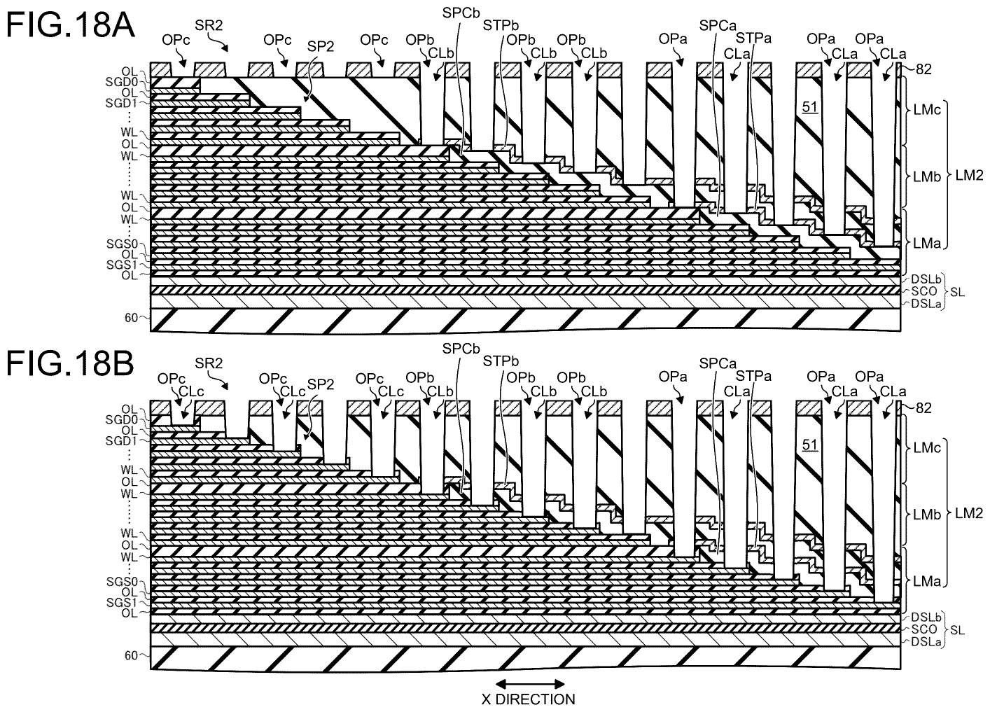

As illustrated in FIG. 18A, a plurality of openings OPc is formed in the mask pattern 82 at positions overlapping, in the stacking direction, the portions where the word lines WL and the like of the stacked body LMc are processed in a staircase shape. At this time, the stopper layer STPa exposed on the bottom surfaces of the plurality of contact holes CLa and the stopper layer STPb exposed on the bottom surfaces of the plurality of contact holes CLb are also etched away, and the plurality of contact holes CLa and CLb are in a state of penetrating the stopper layers STPa and STPb, respectively.

As illustrated in FIG. 18B, the insulating layer 51 covering the staircase portion SP2 is etched via the mask pattern 82 in which the plurality of openings OPc is formed to form a plurality of contact holes CLc penetrating the insulating layer 51 and reaching the individual word lines WL and the like of the stacked body LMc. At this time, the plurality of contact holes CLa and CLb also reach the individual word lines WL and the like of the stacked bodies LMa and LMb.

Thereafter, the plurality of contacts CC is formed by forming the insulating layer 55 and the conductive layer 25 in the contact holes CLa, CLb, and CLc.

Thus, the semiconductor memory device 2 of the modification is manufactured.

With the semiconductor memory device 2 of the modification, the stopper layer STPa disposed at a position overlapping the portions where the plurality of word lines WL and the like of the stacked body LMa are processed in a staircase shape in the stacking direction of the stacked body LM2, and the stopper layer STPb disposed at a height position above the stopper layer STPa and at a position overlapping the portions where the plurality of word lines WL and the like of the stacked bodies LMa and LMb are processed in a staircase shape in the stacking direction of the stacked body LM2 are included. As a result, for example, even in the semiconductor memory device 2 having the stacked body LM2 having the three-tier structure, it is possible to suppress the contacts CC from penetrating the connection target word lines WL or the like.

By the method for manufacturing the semiconductor memory device 2 of the modification, the plurality of contact holes CLb extending from the height position above the stacked body LM2 at the position overlapping the staircase portion SP2 of the stacked body LMb in the stacking direction of the stacked body LM2 and reaching the stopper layer STPb is formed through the mask pattern 82 in which the plurality of openings OPb is formed, and the plurality of contact holes CLa is caused to reach the stopper layer STPa above the staircase portion SP2 of the stacked body LMa.

As described above, since the etching is temporarily stopped by the stopper layer STPb, it is possible to suppress variations in the reach height of these contact holes CLb. In addition, since the etching is temporarily stopped by the stopper layer STPa, variations in the reach height of the plurality of contact holes CLa are also suppressed.

By the method for manufacturing the semiconductor memory device 2 of the modification, the plurality of openings OPc is formed at positions of the mask pattern 82 overlapping the staircase portion SP2 of the stacked body LMc in the stacking direction of the stacked body LM2, and penetrates the stopper layer STPa exposed on the bottom surfaces of the plurality of contact holes CLa and penetrates the stopper layer STPb exposed on the bottom surfaces of the plurality of contact holes CLb.

As described above, since the opening of the mask pattern 82 for forming the contact holes CLc on the upper layer side and the removal of the stopper layers STPa and STPb of the bottom surfaces of the contact holes CLa and CLb on the lower layer side are collectively performed, the number of processes for forming the contacts CC can be reduced.

By the method for manufacturing the semiconductor memory device 2 of the modification, the plurality of contact holes CLc extending from the height position above the stacked body LM2 at the position overlapping the staircase portion SP2 of the stacked body LMc in the stacking direction of the stacked body LM2 and reaching the portions where the plurality of word lines WL and the like of the stacked body LMc are processed in a staircase shape is formed through the mask pattern 82 in which the plurality of openings OPc is formed, and the plurality of contact holes CLa is caused to reach the portions where the plurality of word lines WL and the like of the stacked body LMa are processed in a staircase shape, and the plurality of contact holes CLb is caused to reach the portions where the plurality of word lines WL and the like of the stacked body LMb are processed in a staircase shape.

As described above, since the formation of the contact holes CLc on the upper layer side and the additional processing of the contact holes CLa and CLb on the lower layer side are collectively performed, the number of processes for forming the contacts CC can be reduced. In addition, when the additional etching is performed on the contact holes CLa and CLb on the lower layer side, it is possible to suppress excessive application of over-etching to the word lines WL of the stacked body LMc that are the reach targets of the contact holes CLc on the upper layer side.

Furthermore, since the contact holes CLa and CLb on the lower layer side are stopped above the reach target word lines WL or the like, there is no need to precisely adjust, for example, the etching conditions and the aspect ratios of these contact holes, and it is possible to increase the margin of the etching conditions.

With the semiconductor memory device 2 and the method for manufacturing the semiconductor memory device 2 of the modification, the same effects as those of the above-described embodiment are obtained.

### Other Modifications

Note that in the above-described embodiment and modification, in the method of leading out the plurality of word lines WL and the like on one side, the contacts are alternately disposed in the Y direction every two block regions BLK in the staircase region SR on one side in the X direction. However, in the one-side lead-out method for the word lines WL and the like, it is sufficient if the contacts are disposed on one side in the X direction in the same block region BLK, and the disposition order is not limited to the above.

In addition, in the above-described embodiment and modification, the stacked bodies LM and LM2 having a two-tier structure or a three-tier structure are provided. However, the configuration of the stacked body may be one tier or four tiers or more.

In addition, in the above-described embodiment and modification, the pillars PL are connected to the source line SL on the side surfaces of the channel layers CN, but it is not limited thereto. For example, the pillar may be configured to be connected to the source line at the lower end portion of the channel layer by removing the memory layer on the bottom surface of the pillar.

In addition, in the above-described embodiment and modification, the peripheral circuits CBA are disposed above the stacked body LM. However, the peripheral circuit may be disposed below the stacked body or in the same layer as the stacked body.

In a case where the peripheral circuit is disposed below the stacked body, for example, the source line and the stacked body can be formed on the insulating layer of the semiconductor substrate having the peripheral circuit covered with the insulating layer. In a case where the peripheral circuit is disposed in the same layer as the stacked body, the stacked body can be formed at a position different from the peripheral circuit on the semiconductor substrate on which the peripheral circuit is formed.

Note that the embodiment of the present invention may be implemented in the manner described below.

### (Supplement)

A semiconductor memory device including:
a stacked body in which a plurality of conductive layers is stacked apart from each other;
a staircase portion that is disposed in a part of the stacked body and in which the plurality of conductive layers is processed in a staircase shape;
a spacer layer that is disposed above a part of the staircase portion, has an upper surface processed in a staircase shape, and contains silicon oxide;
a stopper layer that is disposed above the spacer layer, has an upper surface processed in a staircase shape, and contains tungsten;
a plurality of first contacts that extends from a height position above the stacked body at positions overlapping the staircase portion in a stacking direction of the stacked body, and is connected to portions where a plurality of first conductive layers on a lower layer side including a lowermost conductive layer among the plurality of conductive layer is processed in the staircase shape; and
a plurality of second contacts that extends from the height position above the stacked body at positions overlapping the staircase portion in the stacking direction and is connected to portions where a plurality of second conductive layers on an upper layer side including an uppermost conductive layer among the plurality of conductive layers is processed in the staircase shape, wherein
the stopper layer is at least disposed at a position overlapping the portions where the plurality of first conductive layers is processed in the staircase shape in the stacking direction,
the plurality of first contacts penetrates the stopper layer and the spacer layer and extends in the stacking direction,
the plurality of second contacts extends in the stacking direction without penetrating the stopper layer, and
a thickness of the stopper layer is more than a thickness of each of the plurality of conductive layers and less than twice the thickness of each of the plurality of conductive layers.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a stacked body in which a plurality of conductive layers is stacked apart from each other;
a staircase portion that is disposed in a part of the stacked body and in which the plurality of conductive layers is processed in a staircase shape;
a stopper layer that is disposed above a part of the staircase portion;
a plurality of first contacts that extends from a height position above the stacked body at positions overlapping the staircase portion in a stacking direction of the stacked body, and is connected to portions where a plurality of first conductive layers on a lower layer side including a lowermost conductive layer among the plurality of conductive layer is processed in the staircase shape; and
a plurality of second contacts that extends from the height position above the stacked body at positions overlapping the staircase portion in the stacking direction and is connected to portions where a plurality of second conductive layers on an upper layer side including an uppermost conductive layer among the plurality of conductive layers is processed in the staircase shape, wherein
the stopper layer is at least disposed at a position overlapping the portions where the plurality of first conductive layers is processed in the staircase shape in the stacking direction,
the plurality of first contacts penetrates the stopper layer and extends in the stacking direction, and
the plurality of second contacts extends in the stacking direction without penetrating the stopper layer.

2. The semiconductor memory device according to claim 1, wherein
the stopper layer includes a plurality of terrace portions and a plurality of step portions connecting the plurality of terrace portions in the stacking direction, and is disposed along at least a part of the staircase shape of the plurality of conductive layers.

3. The semiconductor memory device according to claim 1, wherein
the stopper layer is at least one selected from the group consisting of a tungsten layer, a tungsten silicon layer, a silicon layer, and an aluminum oxide layer.

4. The semiconductor memory device according to claim 1, wherein
the stopper layer is a tungsten layer.

5. The semiconductor memory device according to claim 4, wherein
a thickness of the stopper layer is more than a thickness of each of the plurality of conductive layers and less than twice the thickness of each of the plurality of conductive layers.

6. The semiconductor memory device according to claim 4, wherein
the plurality of first contacts includes
a core layer having conductivity, and
a liner layer having insulation properties covering a side wall of the core layer.

7. The semiconductor memory device according to claim 6, wherein
a thickness of the liner layer is 1.5 times or more a thickness of each of the plurality of conductive layers.

8. The semiconductor memory device according to claim 6, wherein
a thickness of the liner layer is twice or more a thickness of each of the plurality of conductive layers.

9. The semiconductor memory device according to claim 4, further comprising:
a plate-like portion that extends in the stacked body in a first direction intersecting the stacking direction and in the stacking direction and divides the stacked body in a second direction intersecting both the stacking direction and the first direction, wherein
the stopper layer is disposed at the position away from the plate-like portion in the second direction.

10. The semiconductor memory device according to claim 1, further comprising:
a plurality of third contacts that extends from the height position above the stacked body at positions overlapping the staircase portion in the stacking direction and is connected to portions where a plurality of third conductive layers belonging to layers between the plurality of first and second conductive layers among the plurality of conductive layers is processed in the staircase shape, wherein
the stopper layer includes
a first stopper layer disposed at a position overlapping the portions where the plurality of first conductive layers is processed in the staircase shape in the stacking direction, and
a second stopper layer disposed at a height position above the first stopper layer and at a position overlapping the portions where the plurality of first and third conductive layers are processed in the staircase shape in the stacking direction,
the plurality of first contacts penetrates the first and second stopper layers and extends in the stacking direction, and
the plurality of third contacts penetrates the second stopper layer and extends in the stacking direction.

11. A method for manufacturing a semiconductor memory device, comprising:
forming a first stacked body including a first staircase portion in which a plurality of first sacrificial layers is stacked apart from each other and the plurality of first sacrificial layers is processed in a staircase shape;
forming a first stopper layer above the first staircase portion;
forming, above the first stacked body, a second stacked body in which a plurality of second sacrificial layers is stacked apart from each other and a second staircase portion in which the plurality of second sacrificial layers is processed in a staircase shape is provided on an extension line of the first staircase portion;
forming a plurality of first and second conductive layers, respectively, by replacing the plurality of first and second sacrificial layers with a conductive material;
forming a plurality of first contacts that extends from a height position above the first and second stacked bodies at positions overlapping the first staircase portion in a stacking direction of the first and second stacked bodies and is connected to portions where the plurality of first conductive layers is processed in a staircase shape; and
forming a plurality of second contacts that extends from the height position above the first and second stacked bodies at positions overlapping the second staircase portion in the stacking direction and is connected to portions where the plurality of second conductive layers is processed in a staircase shape, wherein
forming the plurality of first and second contacts includes
forming, via a mask pattern, a plurality of first contact holes extending from the height position above the first and second stacked bodies at the positions overlapping the first staircase portion in the stacking direction and reaching the first stopper layer,
forming a plurality of first openings at positions of the mask pattern and penetrating the first stopper layer exposed on bottom surfaces of the plurality of first contact holes, the positions at which the plurality of first openings is formed overlapping the second staircase portion in the stacking direction, and
forming, via the mask pattern in which the plurality of first openings is formed, a plurality of second contact holes extending from the height position above the first and second stacked bodies at the positions overlapping the second staircase portion in the stacking direction and reaching the portions where the plurality of second conductive layers is processed in the staircase shape, and causing the plurality of first contact holes to reach the portions where the plurality of first conductive layers is processed in the staircase shape.

12. The method for manufacturing a semiconductor memory device according to claim 11, further comprising:
forming a spacer layer including a plurality of terrace portions and a plurality of step portions connecting the plurality of terrace portions in the stacking direction, and covering the first staircase portion along at least a part of the staircase shape of the plurality of first sacrificial layers, wherein
the first stopper layer is formed on the spacer layer.

13. The method for manufacturing a semiconductor memory device according to claim 11, wherein
the first stopper layer is at least one of selected from the group consisting a tungsten layer, a tungsten silicon layer, a silicon layer, and an aluminum oxide layer.

14. The method for manufacturing a semiconductor memory device according to claim 11, wherein
the first stopper layer is a tungsten layer.

15. The method for manufacturing a semiconductor memory device according to claim 14, wherein
the first stopper layer is formed to have a thickness more than a thickness of each of the plurality of conductive layers and less than twice the thickness of each of the plurality of conductive layers.

16. The method for manufacturing a semiconductor memory device according to claim 14, wherein
forming the plurality of first contacts includes
forming a liner layer having insulation properties covering a side wall of each of the plurality of first contact holes, and
filling each of the plurality of first contact holes covered with the liner layer with a core layer having conductivity.

17. The method for manufacturing a semiconductor memory device according to claim 16, wherein
the liner layer is formed to have a thickness 1.5 times or more a thickness of each of the plurality of conductive layers.

18. The method for manufacturing a semiconductor memory device according to claim 16, wherein
the liner layer is formed to have a thickness twice or more a thickness of each of the plurality of conductive layers.

19. The method for manufacturing a semiconductor memory device according to claim 11, wherein
the first stopper layer is formed to contain a same type of material as the mask pattern.

20. The method for manufacturing a semiconductor memory device according to claim 11, further comprising:
forming, above the first stacked body, after forming the first stacked body and before forming the second stacked body, a third stacked body in which a third staircase portion in which a plurality of third sacrificial layers is stacked apart from each other and the plurality of third sacrificial layers is processed in a staircase shape is formed to be continuous with the first staircase portion;
forming a second stopper layer disposed at a height position above the first stopper layer and at a position overlapping the portions where the plurality of first and third conductive layers are processed in a staircase shape in the stacking direction;
forming a plurality of third conductive layers by replacing the plurality of third sacrificial layers located in layers between the plurality of first and second sacrificial layers with the conductive material together with the plurality of first and second sacrificial layers; and
forming a plurality of third contacts that extends from the height position above the first and third stacked bodies at positions overlapping the third staircase portion in the stacking direction and is connected to portions where the plurality of third conductive layers is processed in the staircase shape, wherein
forming the plurality of first to third contacts includes
forming, via the mask pattern, the plurality of first contact holes extending from a height position above the first to third stacked bodies at the positions overlapping the first staircase portion in the stacking direction and reaching the second stopper layer,
forming a plurality of second openings at positions of the mask pattern, and penetrating the second stopper layer exposed on bottom surfaces of the plurality of first contact holes, the positions at which the plurality of second openings is formed overlapping the third staircase portion in the stacking direction,
forming a plurality of third contact holes extending from the height position above the first to third stacked bodies at the positions overlapping the third staircase portion in the stacking direction and reaching the second stopper layer via the mask pattern in which the plurality of second openings is formed, and causing the plurality of first contact holes to reach the first stopper layer,
forming the plurality of first openings at positions of the mask pattern, penetrating the first stopper layer exposed on the bottom surfaces of the plurality of first contact holes, and penetrating the second stopper layer exposed on bottom surfaces of the plurality of third contact holes, the positions at which the plurality of first openings is formed overlapping the second staircase portion in the stacking direction, and
forming the plurality of second contact holes extending from the height position above the first to third stacked bodies at the positions overlapping the second staircase portion in the stacking direction and reaching the portions where the plurality of second conductive layers is processed in the staircase shape through the mask pattern in which the plurality of first openings is formed, causing the plurality of first contact holes to reach the portions where the plurality of first conductive layers is processed in the staircase shape, and causing the plurality of third contact holes to reach the portions where the plurality of third conductive layers is processed in the staircase shape.
